(19) United States
(12) Patent Application Publication
(10) Pub. No.: US 2025/0180626 A1
(43) Pub. Date: Jun. 5, 2025

(54) APPARATUS AND METHOD FOR ESTIMATING TEMPERATURE AND MAIN CURRENT OF POWER SEMICONDUCTOR ELEMENT

(71) Applicant: Mitsubishi Electric Corporation, Tokyo (JP)

(72) Inventor: Yukihiko WADA, Chiyoda-ku, Tokyo (JP)

(73) Assignee: Mitsubishi Electric Corporation, Tokyo (JP)

(21) Appl. No.: 18/845,892

(22) PCT Filed: Mar. 28, 2022
(86) PCT No.: PCT/JP2022/015087

§ 371 Date: Sep. 11, 2024

(51) Int. Cl. G01R 31/26

(52) U.S. Cl. CPC G01R 31/2619

(57) ABSTRACT

In a semiconductor characteristics measuring apparatus, a first potential difference measuring device measures a first potential difference between two connection terminals connected to first and second main electrodes, respectively, of a power semiconductor element. A second potential difference measuring device measures a second potential difference between two connection terminals connected at different positions of a current path of a main current to or from the second main electrode. When values of an element temperature and a main current specified based on a measurement value of the first potential difference match values of an element temperature and a main current specified based on a measurement value of the second potential difference, a processing device outputs the matching values of the element temperature and the main current as estimates at a present time point.

### TECHNICAL FIELD

The present disclosure relates to a semiconductor characteristics measuring apparatus, a semiconductor characteristics measuring method, and a program.

### BACKGROUND ART

In equipment including a semiconductor device such as a power semiconductor module, the soundness of the equipment can be ensured by monitoring a state of the semiconductor device. In order to do so, it is necessary to know a current flowing through the semiconductor device and a temperature of the semiconductor device. If these can be measured accurately, a characteristics margin of the semiconductor device can be minimized, which leads to a reduction in cost. It is desirable that a method for knowing the current and the temperature should be as simple as possible and as low cost as possible. That is, it is desirable to measure the current and the temperature without using a sensor specialized for current detection and a sensor specialized for temperature detection. The following are examples of the relevant conventional techniques.

International Publication No. 2020/261385 (PTL 1) discloses the technique of estimating a temperature by using the fact that a voltage between an emitter terminal and an emitter reference terminal changes dependently on the temperature when a collector current flowing through a power semiconductor element is constant.

In the technique disclosed in Japanese Patent Laying-Open No. 2016-63674 (PTL 2), a current value is obtained by controlling a voltage of a sense cell of a power semiconductor element by use of a controller. Furthermore, a change in gate threshold voltage is measured by measuring a gate voltage of the power semiconductor element, and a temperature is estimated based on the measured change in gate threshold voltage.

In the technique disclosed in Japanese Patent Laying-Open No. 2021-19435 (PTL 3), a flowing current is estimated from a switching speed of a power semiconductor device. Furthermore, an ON voltage of the power semiconductor device is measured and a temperature is estimated from the temperature dependency thereof.

### CITATION LIST

### Patent Literature

PTL 1: International Publication No. 2020/261385
PTL 2: Japanese Patent Laying-Open No. 2016-63674
PTL 3: Japanese Patent Laying-Open No. 2021-19435

### SUMMARY OF INVENTION

### Technical Problem

In the conventional techniques described above, either a current sensor or a temperature sensor is required to measure the current and the temperature, or a sense cell is required in a power semiconductor element, or a complicated and high-cost apparatus such as a voltage controller, a gate voltage measuring apparatus or a switching speed measuring apparatus is required.

The present disclosure has been made in view of the above-described problem, and an object thereof is to provide the technique that allows simultaneous estimation of a value of a current flowing through a semiconductor device and a temperature by simple means that does not use a current sensor and a temperature sensor and does not require a complicated controller.

### Solution to Problem

In an embodiment, a semiconductor characteristics measuring apparatus for estimating a temperature of a semiconductor device and a main current flowing through the semiconductor device is provided. The semiconductor device includes: a power semiconductor element; and a plurality of connection terminals. The power semiconductor element has a first main electrode, a second main electrode, and a control electrode to control the main current flowing between the first main electrode and the second main electrode. Each of the plurality of connection terminals is connected to any one of the first main electrode, the second main electrode and the control electrode. The semiconductor characteristics measuring apparatus includes: a first potential difference measuring device; a second potential difference measuring device; a storage device; and a processing device. The first potential difference measuring device measures a first potential difference based on a potential difference between two connection terminals connected to the first main electrode and the second main electrode, respectively, of the plurality of connection terminals. The second potential difference measuring device measures a second potential difference between a first connection terminal and a second connection terminal of the plurality of connection terminals, the first connection terminal being connected to a current path of the main current to or from the second main electrode, the second connection terminal being connected to the second main electrode or connected to the current path at a position closer to the second main electrode than the first connection terminal. The storage device stores data indicating a first relationship and data indicating a second relationship, the first relationship being a relationship among the first potential difference, a temperature of the power semiconductor element and the main current, the second relationship being a relationship among the second potential difference, the temperature of the power semiconductor element and the main current. The processing device obtains a measurement value of the first potential difference from the first potential difference measuring device, and obtains a measurement value of the second potential difference from the second potential difference measuring device. The processing device specifies, from the data indicating the first relationship, a value of the temperature of the power semiconductor element and a value of the main current corresponding to the measurement value of the first potential difference, and specifies, from the data indicating the second relationship, a value of the temperature of the power semiconductor element and a value of the main current corresponding to the measurement value of the second potential difference. When the value of the temperature of the power semiconductor element and the value of the main current specified based on the measurement value of the first potential difference match the value of the temperature of the power semiconductor element and the value of the main current specified based on the measurement value of the second potential difference, the processing device outputs the matching value of the temperature and the matching value of the main current as estimates at a present time point.

### Advantageous Effects of Invention

According to the embodiment described above, the semiconductor characteristics measuring apparatus can simultaneously estimate the value of the current flowing through the semiconductor device and the temperature with a simple configuration including the first potential difference measuring device, the second potential difference measuring device, the storage device, and the processing device.

### BRIEF DESCRIPTION OF DRAWINGS

FIG. 1A is a configuration diagram of a semiconductor characteristics measuring apparatus according to a first embodiment.

FIG. 1B is a diagram showing a modification of the semiconductor characteristics measuring apparatus shown in FIG. 1A.

FIG. 1C is a diagram showing another modification of the semiconductor characteristics measuring apparatus shown in FIG. 1A.

FIG. 2 is a diagram for illustrating an operation principle of the semiconductor characteristics measuring apparatus shown in FIG. 1A.

FIG. 3A is a flowchart showing a process procedure performed by a processing device of the semiconductor characteristics measuring apparatus shown in FIG. 1A.

FIG. 3B is a flowchart showing the process procedure performed by the processing device of the semiconductor characteristics measuring apparatus shown in FIG. 1A.

FIG. 4 is a configuration diagram of a semiconductor characteristics measuring apparatus according to a second embodiment.

FIG. 5 is a diagram for illustrating an operation principle of the semiconductor characteristics measuring apparatus shown in FIG. 4.

FIG. 6A is a flowchart showing a process procedure performed by a processing device of the semiconductor characteristics measuring apparatus shown in FIG. 4.

FIG. 6B is a flowchart showing the process procedure performed by the processing device of the semiconductor characteristics measuring apparatus shown in FIG. 4.

FIG. 7 is a diagram for illustrating an operation principle of a semiconductor characteristics measuring apparatus according to a third embodiment.

FIG. 8A is a flowchart showing the operation of a processing device of the semiconductor characteristics measuring apparatus according to the third embodiment.

FIG. 8B is a flowchart showing the operation of the processing device of the semiconductor characteristics measuring apparatus according to the third embodiment.

FIG. 9 is a configuration diagram of a semiconductor characteristics measuring apparatus according to a fourth embodiment.

FIG. 10 is a diagram for illustrating an operation example of a processing device shown in FIG. 9.

FIG. 11A is a flowchart showing a process procedure performed by the processing device of the semiconductor characteristics measuring apparatus shown in FIG. 9.

FIG. 11B is a flowchart showing the process procedure performed by the processing device of the semiconductor characteristics measuring apparatus shown in FIG. 9.

### DESCRIPTION OF EMBODIMENTS

Embodiments will be described in detail hereinafter with reference to the drawings. The same or corresponding portions are denoted by the same reference characters and description thereof will not be repeated.

### First Embodiment

### [Configuration of Semiconductor Characteristics Measuring Apparatus]

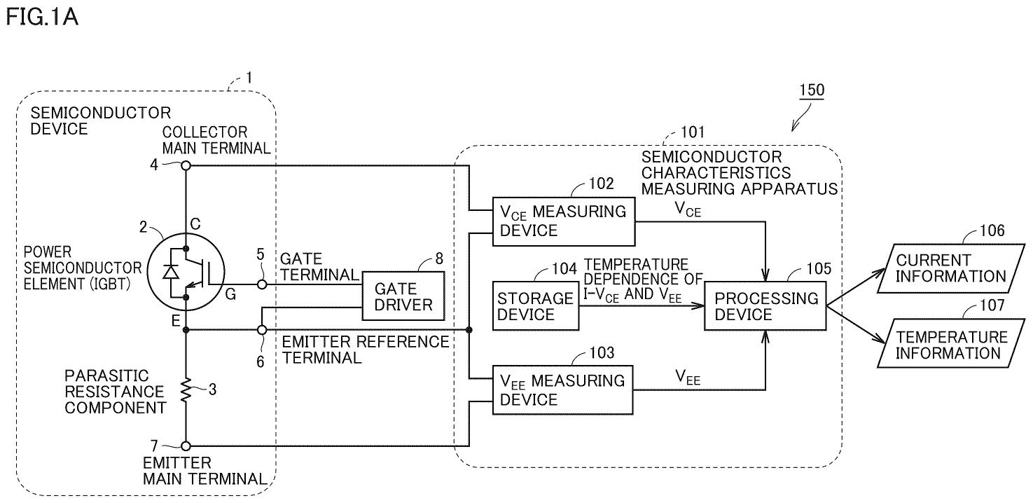

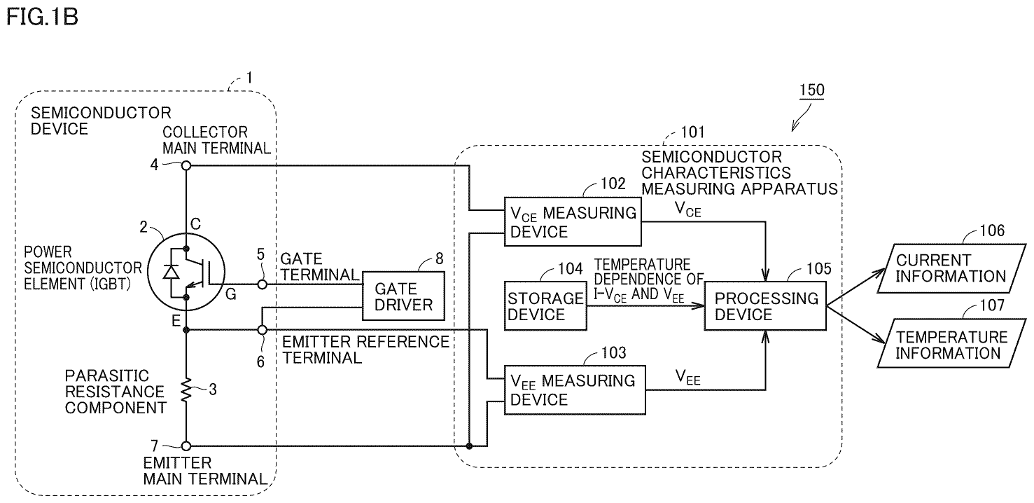

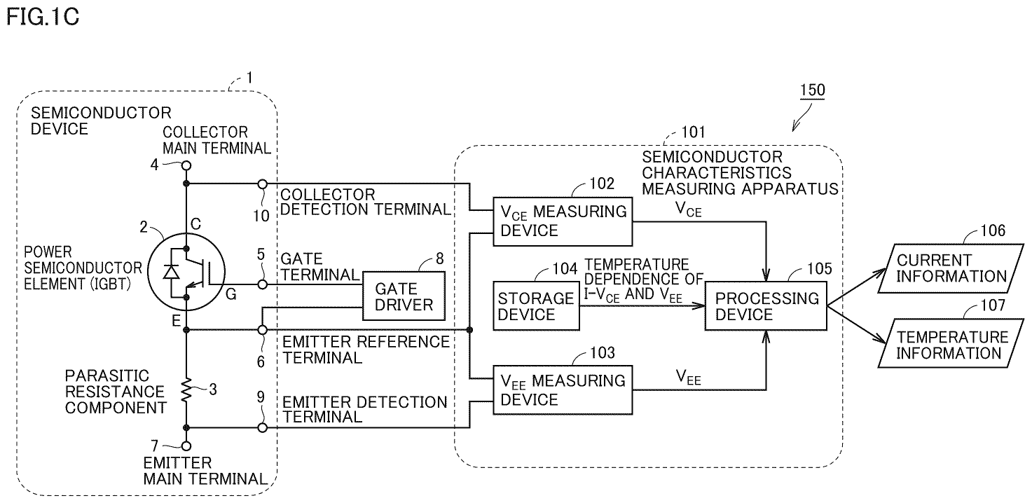

FIG. 1A is a configuration diagram of a semiconductor characteristics measuring apparatus 101 according to a first embodiment. Referring to FIG. 1A, semiconductor characteristics measuring apparatus 101 includes a first potential difference measuring device 102, a second potential difference measuring device 103, a storage device 104, and a processing device 105.

FIG. 1A further shows a semiconductor device 1 to be measured by semiconductor characteristics measuring apparatus 101. Semiconductor device 1 includes a power semiconductor element 2, a collector main terminal 4, a gate terminal 5, an emitter reference terminal 6, and an emitter main terminal 7, Semiconductor device 1, a gate driver 8, semiconductor characteristics measuring apparatus 101 and the like may constitute a power module 150.

In the example shown in FIG. 1A, an insulated gate bipolar transistor (IGBT) is used as power semiconductor element 2 built into semiconductor device 1. In this case, collector main terminal 4 is connected to a collector electrode C of the IGBT, gate terminal 5 is connected to a gate electrode G of the IGBT, and emitter main terminal 7 is connected to an emitter electrode E of the IGBT. A main current of power semiconductor element 2 flows through collector main terminal 4 and emitter main terminal 7. Emitter reference terminal 6 is connected to emitter electrode E and is connected to gate driver 8 described below. A parasitic resistance component 3 is present in a wire between emitter main terminal 7 and emitter electrode E of the IGBT.

Gate driver 8 is connected between gate terminal 5 and emitter reference terminal 6 of semiconductor device 1. Gate driver 8 supplies a drive voltage between the gate electrode and the emitter electrode of the IGBT.

In the present disclosure, more generally, the collector electrode may be referred to as a first main electrode, the emitter electrode may be referred to as a second main electrode, and the gate electrode may be referred to as a control electrode. The gate electrode is provided to control the main current flowing between the first main electrode and the second main electrode. In addition, collector main terminal 4, gate terminal 5, emitter reference terminal 6, and emitter main terminal 7 provided in semiconductor device 1 may be referred to as connection terminals 4 to 7, respectively. Each of connection terminals 4 to 7 is connected to any one of the first main electrode, the second main electrode and the control electrode.

First potential difference measuring device 102 of semiconductor characteristics measuring apparatus 101 is connected to collector main terminal 4 and emitter reference terminal 6 of semiconductor device 1. First potential difference measuring device 102 measures a first potential difference between collector main terminal 4 and emitter reference terminal 6. Since the IGBT is used as power semiconductor element 2 in the example shown in FIG. 1A, the first potential difference is denoted as V_{CE} (i.e., a collector-to-emitter voltage).

Second potential difference measuring device 103 is connected to emitter reference terminal 6 and emitter main terminal 7 of semiconductor device 1. Second potential difference measuring device 103 measures a second potential difference between emitter reference terminal 6 and emitter main terminal 7. Since the IGBT is used as power semiconductor element 2 in the example shown in FIG. 1A, the second potential difference is denoted as V_{EE}.

Storage device 104 stores data indicating a first relationship among the preliminarily measured or calculated first potential difference, the main current and a junction temperature, and data indicating a second relationship among the preliminarily measured or calculated second potential difference, the main current and the junction temperature. Hereinafter, the main current of semiconductor device 1 will also be denoted simply as a current.

Processing device 105 simultaneously estimates the main current and the junction temperature of semiconductor device 1 based on the first potential difference measured by first potential difference measuring device 102, the second potential difference measured by second potential difference measuring device 103, and correlation data of the first relationship and correlation date of the second relationship obtained from storage device 104. Processing device 105 outputs the estimated main current as current information 106 and outputs the estimated temperature as temperature information 107. Hereinafter, the main current of semiconductor device 1 is denoted as I_{C} because the main current of semiconductor device 1 is a collector current of the IGBT, and the temperature of semiconductor device 1 is denoted as T_{J} because the temperature of semiconductor device 1 is a junction temperature of the IGBT.

A hardware configuration of semiconductor characteristics measuring apparatus 101 is not particularly limited. For example, each of first potential difference measuring device 102 and second potential difference measuring device 103 may be implemented by an analog/digital converter. A non-volatile semiconductor memory such as a flash memory may be used as storage device 104, or a hard disk may be used as storage device 104. Processing device 105 may be configured based on a microcomputer including a central processing unit (CPU) and a memory, may be configured using a field programmable gate array (FPGA), or may be configured by dedicated circuitry. Alternatively, processing device 105 may be configured by two or more combinations of these components.

A modification of the connection between first potential difference measuring device 102 and semiconductor device 1 will be supplementarily described below with reference to FIGS. 1B and 1C.

FIG. 1B is a diagram showing a modification of semiconductor characteristics measuring apparatus 101 shown in FIG. 1A. As shown in FIG. 1B, first potential difference measuring device 102 may be connected between collector main terminal 4 and emitter main terminal 7 of semiconductor device 1, and may be configured to measure a potential difference between collector main terminal 4 and emitter main terminal 7. Since a voltage drop caused by parasitic resistance component 3 is approximately one order of magnitude smaller than collector-to-emitter voltage V_{CE} of power semiconductor element 2, the measured potential difference between collector main terminal 4 and emitter main terminal 7 may be defined as first potential difference V_{CE}, which does not lead to a large error. Alternatively, a value obtained by subtracting second potential difference V_{EE} between emitter reference terminal 6 and emitter main terminal 7 from the potential difference between collector main terminal 4 and emitter main terminal 7 may be defined as first potential difference V_{CE}.

As another modification, when a collector reference terminal (not present in FIGS. 1A and 1B) connected to collector electrode C of power semiconductor element 2 is provided separately from collector main terminal 4 through which the main current flows, first potential difference measuring device 102 may measure a potential difference between the collector reference terminal and emitter reference terminal 6 as first potential difference V_{CE}. However, since a current path from collector electrode C to collector main terminal 4 is a copper plate attached to a rear surface (collector) of a semiconductor chip, a parasitic resistance component thereof is extremely small and hardly contributes to an error. In contrast, since emitter electrode E and emitter main terminal 7 on a front surface of the semiconductor chip is connected by an aluminum wire, a non-negligible resistance component is present. Therefore, emitter reference terminal 6 is provided for connection of gate driver 8. In order to reduce an error, it is desirable that first potential difference measuring device 102 should also be connected to emitter reference terminal 6.

FIG. 1C is a diagram showing still another modification of semiconductor characteristics measuring apparatus 101 shown in FIG. 1A. In semiconductor device 1 shown in FIG. 1C, an emitter detection terminal 9 for connecting second potential difference measuring device 103 is provided separately from emitter main terminal 7, and a collector detection terminal 10 for connecting to first potential difference measuring device 102 is provided separately from collector main terminal 4. In this case, it is possible to prevent the main current from flowing through the connection terminals to which each of first potential difference measuring device 102 and second potential difference measuring device 103 is connected.

Therefore, in view of each of the above-described modifications, more generally, first potential difference measuring device 102 measures a first potential difference based on a potential difference between two connection terminals (between collector main terminal 4 or collector detection terminal 10 and emitter reference terminal 6 or emitter main terminal 7) connected to the first main electrode and the second main electrode (one is collector electrode C and the other is emitter electrode E), respectively, of the plurality of connection terminals provided in semiconductor device 1. Second potential difference measuring device 103 measures a second potential difference between a first connection terminal (emitter main terminal 7 or emitter detection terminal 9) and a second connection terminal (emitter reference terminal 6) of the plurality of connection terminals, the first connection terminal being connected to a current path of the main current to or from the second main electrode (emitter electrode E), the second connection terminal being connected to the second main electrode or the current path at a position closer to the second main electrode (emitter electrode E) than the first connection terminal.

### [Operation Principle of Semiconductor Characteristics Measuring Apparatus]

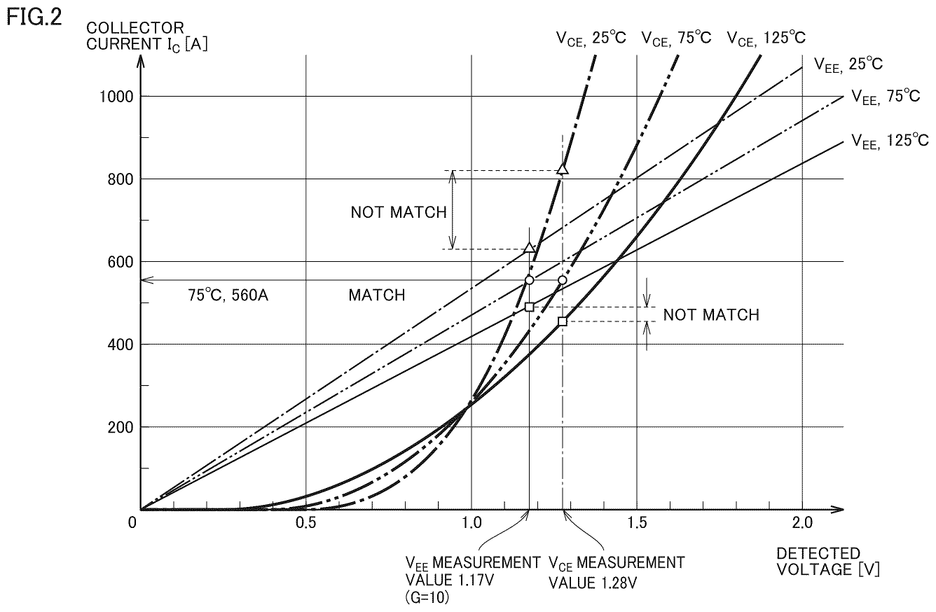

An operation principle of semiconductor characteristics measuring apparatus 101 configured as described above will now be described. FIG. 2 is a diagram for illustrating an operation principle of semiconductor characteristics measuring apparatus 101 shown in FIG. 1A.

In FIG. 2, the first relationship and the second relationship stored in storage device 104 of semiconductor characteristics measuring apparatus 101 are shown in the form of graph. The first relationship is a relationship among first potential difference V_{CE}, current I_{C} and temperature T_{J}. The second relationship is a relationship among second potential difference V_{EE}, current I_{C} and temperature T_{J}.

More specifically, in FIG. 2, the relationship between first potential difference V_{CE} and current I_{C} is traced as the first relationship by three thick lines in accordance with the three types of temperatures T_{J}, with the horizontal axis representing first potential difference V_{CE} and the vertical axis representing current I_{C}. The three types of temperatures T_{J} are 25° C., 75° C. and 125° C. The relationship between first potential difference V_{CE} and current I_{C} when temperature T_{J} is 25° C. is indicated by a thick dash-dot line, the relationship between first potential difference V_{CE} and current I_{C} when temperature T_{J} is 75° C. is indicated by a thick dash-dot-dot line, and the relationship between first potential difference V_{CE} and current I_{C} when temperature T_{J} is 125° C. is indicated by a thick solid line.

Similarly, in FIG. 2, the relationship between second potential difference V_{EE} and current I_{C} is traced as the second relationship by three thin lines in accordance with the three types of temperatures T_{J}, with the horizontal axis representing second potential difference V_{EE} and the vertical axis representing current I_{C}. The three types of temperatures T_{J} are 25° C., 75° C. and 125° C. The relationship between second potential difference V_{EE} and current I_{C} when temperature T_{J} is 25° C. is indicated by a thin dash-dot line, the relationship between second potential difference V_{EE} and current I_{C} when temperature T_{J} is 75° C. is indicated by a thin dash-dot-dot line, and the relationship between second potential difference V_{EE} and current I_{C} when temperature Ty is 125° C. is indicated by a thin solid line. However, unlike the case of first potential difference V_{CE}, a gain G=10, i.e., a value obtained by multiplying the actual value of second potential difference V_{EE} by 10 is plotted in the case of second potential difference V_{EE}. The reason for this is to make the value of second potential difference V_{EE} easier to see on the graph because the value of second potential difference V_{EE} IS generally approximately one order of magnitude smaller than first potential difference V_{CE}.

As can be seen from FIG. 2, the relationship between current I_{C} and first potential difference V_{CE} has non-linearity and is expressed by the curved line on the current-voltage graph. In contrast, the relationship between current I_{C} and second potential difference V_{EE} has linearity and is expressed by the straight line passing through the origin on the current-voltage graph. This difference is due to a difference between a mechanism of generation of first potential difference V_{CE} and a mechanism of generation of second potential difference V_{EE}.

First potential difference V_{CE} corresponds to the voltage between the main electrodes of the power semiconductor device, which is here the voltage between the collector and the emitter of the IGBT. Collector-to-emitter voltage V_{CE} of the IGBT is non-linear to collector current I_{C}. Specifically, when collector current I_{C} is small, collector-to-emitter voltage V_{CE} has a large value as compared with collector current I_{C}. In contrast, when collector current I_{C} is large, collector-to-emitter voltage V_{CE} has a not very large value as a ratio to collector current I_{C}. As a result, a large current can be passed through the IGBT at a relatively small ON voltage and power loss. Since the IGBT itself has such a non-linear characteristic, the relationship between current I_{C} and first potential difference V_{CE} is non-linear.

On the other hand, second potential difference V_{EE} mostly reflects the voltage generated between both ends of parasitic resistance component 3 on the emitter side of semiconductor device 1, Parasitic resistance component 3 on the emitter side of semiconductor device 1 is mostly composed of a resistance component of the bonding wires made of aluminum. Therefore, the relationship between main current I_{C} and second potential difference V_{EE} is linear.

As to the temperature dependence of first potential difference V_{CE}, at a certain threshold current or more, a resistance value between the collector and the emitter becomes higher as the temperature becomes higher. That is, first potential difference V_{CE} becomes larger as compared with main current I_{C} as the temperature becomes higher. Conversely, at the above-described threshold current or less, the resistance value between the collector and the emitter becomes lower as the temperature becomes higher. That is, V_{CE} becomes smaller as compared with main current I_{C} as the temperature becomes higher.

On the other hand, as to the temperature dependence of second potential difference V_{EE}, a resistance value between emitter main terminal 7 and emitter reference terminal 6 becomes higher as the temperature becomes higher. That is, second potential difference V_{EE} becomes larger as compared with main current I_{C} as the temperature becomes higher. This feature reflects the temperature dependence of the electrical resistance of the aluminum material.

As described above, the first relationship and the second relationship have different features in terms of linearity and temperature dependence. Semiconductor characteristics measuring apparatus 101 according to the present embodiment simultaneously measures the current flowing through the semiconductor device and the temperature using these features. An overview of the operation of processing device 105 of semiconductor characteristics measuring apparatus 101 will be described below with reference to FIG. 2.

As an example, measured first potential difference V_{CE} is assumed to be 1.28 V, and a value obtained by multiplying measured second potential difference V_{EE} by 10 (G=10) is assumed to be 1.17 V. These values are shown on the horizontal axis in FIG. 2.

A straight line (indicated by a dash-dot line in FIG. 2) is drawn in parallel with the vertical axis from the point of V_{CE}=1.28 V on the horizontal axis in FIG. 2, and intersection points between this straight line and the group of thick curved lines indicating the first relationship (i.e., a I_{C}−V_{CE} characteristic) are obtained. As a result, current value I_{C} corresponding to V_{CE}=1.28 V can be specified. However, since temperature T_{J} is unknown, there are many candidates of current value I_{C}. In FIG. 2, the intersection points with the group of thick curved lines in the case of 25° C., 75° C. and 125° C. are indicated by the triangle mark, the circle mark and the square mark, respectively.

Similarly, a straight line (indicated by a solid line in FIG. 2) is drawn in parallel with the vertical axis from the point of V_{EE}×10=1.17 V on the horizontal axis in FIG. 2, and intersection points between this straight line and the group of thin straight lines indicating the second relationship (i.e., a I_{C}−V_{EE} characteristic) are obtained. As a result, current I_{C} corresponding to V_{EE}×10=1.17 V can be specified. However, since temperature T_{J} is unknown, there are many candidates of current value I_{C}. In FIG. 2, the intersection points with the group of thin straight lines in the case of 25° C., 75° C. and 125° C. are indicated by the triangle mark, the circle mark and the square mark, respectively.

In the foregoing, many candidate values of current I_{C} and temperature T_{J} were obtained from the measurement value of first potential difference V_{CE} and the measurement value of second potential difference V_{EE}. Here, there is such a constraint condition that the values of current I_{C} and temperature T_{J} obtained from first potential difference V_{CE} must match the values of current I_{C} and temperature T_{J} obtained from second potential difference V_{EE}. The reason for this is obvious because collector current I_{C} and junction temperature T_{J} of the same semiconductor device 1 are measured.

Here, assuming that T_{J}=25° C., for example, current I_{C} obtained from first potential difference V_{CE} (corresponding to the triangle mark on the thick dash-dot line) and current I_{C} obtained from second potential difference V_{EE} (corresponding to the triangle mark on the thin dash-dot line) are different. That is, the triangle mark obtained from first potential difference V_{CE} is located at a position higher than that of the triangle mark obtained from second potential difference V_{EE}. This is inconsistent with the constraint condition that current I_{C} of the same semiconductor device is measured. Therefore, the assumption of temperature T_{J} is concluded as being incorrect.

Next, assuming that T_{J}=125° C., current I_{C} obtained from first potential difference V_{CE} (corresponding to the square mark on the thick solid line) and current I_{C} obtained from second potential difference V_{EE} (corresponding to the square mark on the thin solid line) are different. That is, the square mark obtained from first potential difference V_{CE} is located at a position lower than that of the square mark obtained from second potential difference V_{EE}. This is inconsistent with the constraint condition that current I_{C} of the same semiconductor device is measured. Therefore, the assumption of T_{J}=125° C. is concluded as being incorrect.

Next, assuming that T_{J}=75° C., current I_{C} obtained from first potential difference V_{CE} (corresponding to the circle mark on the thick dash-dot-dot line) matches current I_{C} obtained from second potential difference V_{EE} (corresponding to the circle mark on the thin dash-dot-dot line). That is, the circle mark obtained from first potential difference V_{CE} and the circle mark obtained from second potential difference V_{EE} are located at the same height. This meets the constraint condition that I_{C} of the same semiconductor device is measured. Therefore, temperature T_{J} and current I_{C} in this case are values to be obtained. T_{J}=75° C. and I_{C}=560 A are determined from FIG. 2.

### [Specific Process Contents by Processing Device of Semiconductor Characteristics Measuring Apparatus]

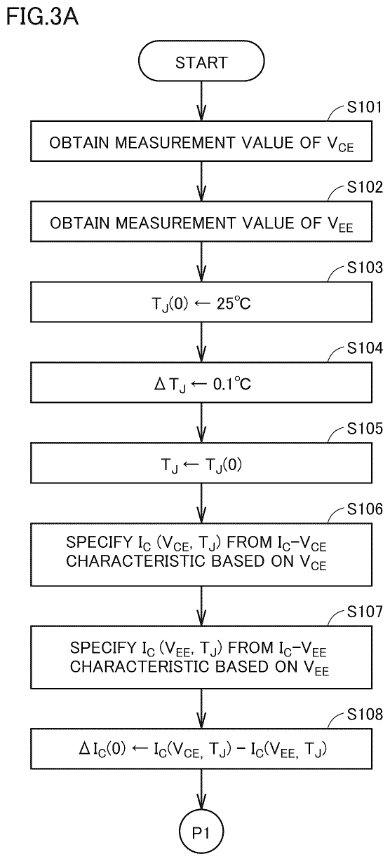

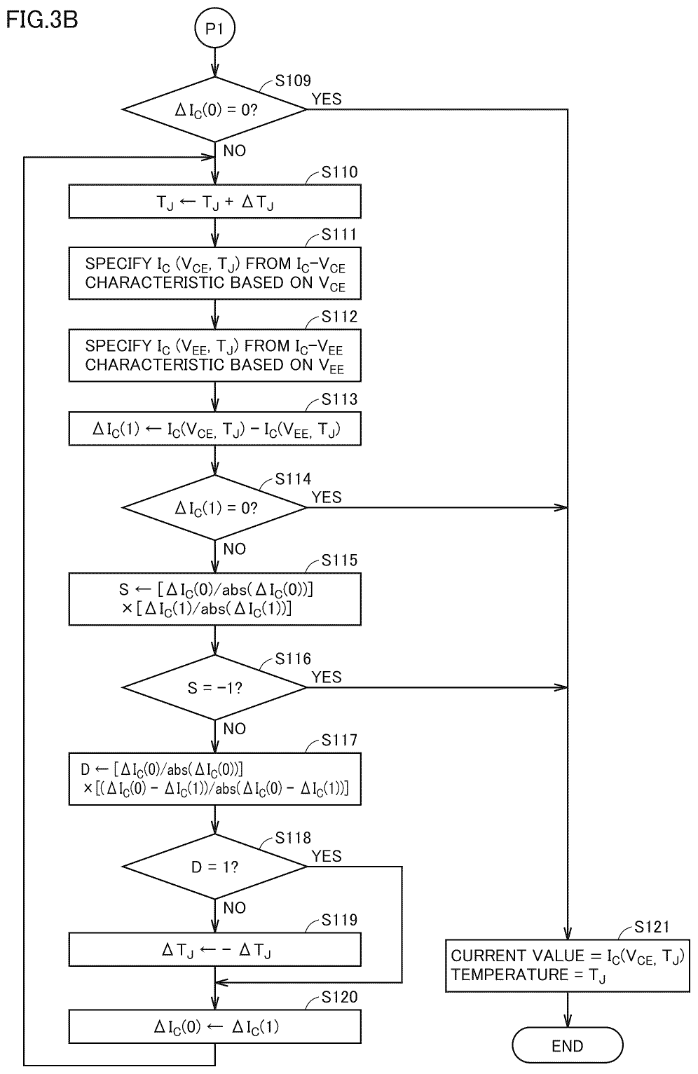

The process contents by processing device 105 whose overview is described above will now be specifically described with reference to FIGS. 3A and 3B. FIGS. 3A and 3B are flowcharts each showing a process procedure performed by processing device 105 of semiconductor characteristics measuring apparatus 101 shown in FIG. 1A.

In first steps S101 and S102, processing device 105 obtains a measurement value of first potential difference V_{CE} from first potential difference measuring device 102, and obtains a measurement value of second potential difference V_{EE} from second potential difference measuring device 103. Either step S101 or step S102 may be performed first, or steps S101 and S102 may be performed simultaneously.

In next steps S103 and S104, processing device 105 sets T_{J}(0), which is an initial value of temperature T_{J}, to 25° C. and sets a step width ΔT_{J} of temperature T_{J} to 0.1° C., for example. Either step S103 or step S104 may be performed first, or steps S103 and S104 may be performed simultaneously. Alternatively, steps S103 and S104 may be performed before steps S101 and S102.

In next step S105, processing device 105 substitutes T_{J}(0) into temperature T_{J}. This processing means that initial value T_{J}(0) is set as a candidate value of temperature T_{J}.

In next step S106, processing device 105 specifies a value of a current I_{C} (V_{CE}, Ti) corresponding to the measurement value of first potential difference V_{CE} and the candidate value of temperature T_{J} from the I_{C}−V_{CE} characteristic based on the measurement value of first potential difference V_{CE}. This processing means that the value of current I_{C} at specified first potential difference V_{CE} is read from the curved line indicating the I_{C}−V_{CE} characteristic at specified temperature T_{J}.

In next step S107, processing device 105 specifies a value of a current I_{C} (V_{EE}, T_{J}) corresponding to second potential difference V_{CE} and the candidate value of temperature T_{J} from the I_{C}−V_{EE} characteristic based on the measurement value of second potential difference V_{EE}. This processing means that current I_{C} at specified second potential difference V_{EE} is read from the straight line indicating the I_{C}−V_{EE} characteristic at specified temperature T_{J}. Either step S106 or step S107 may be performed first, or steps S106 and S107 may be performed simultaneously.

In next step S108, processing device 105 calculates a difference I_{C} (V_{CE}, T_{J})−I_{C} (V_{EE}, T_{J}) between the two current values specified in steps S106 and S107, and substitutes the calculation result into ΔI_{C}(0). ΔI_{C}(0) refers to, in the case of repeatedly calculating a difference between two current values I_{C} while changing the candidate value of temperature T_{J}, a difference between the current values calculated with respect to a previously set candidate value of temperature T_{J}.

In next step S109, processing device 105 determines whether difference ΔI_{C}(0) between two current values I_{C} calculated in step S108 is equal to 0. When ΔI_{C}(0)=0 is satisfied (YES in step S109), the value of current I_{C} obtained from first potential difference V_{CE} matches the value of current I_{C} obtained from second potential difference V_{EE}. Therefore, in next step S121, processing device 105 outputs present I_{C} (V_{CE}, T_{J}) as an estimate of the current and outputs the present candidate value of temperature T_{J} as an estimate of the temperature, and then, ends the process.

In contrast, when ΔI_{C}(0)=0 is not satisfied (NO in step S109), processing device 105 moves the process to step S110. In step S110, processing device 105 sets a temperature T_{J}+ΔT_{J} obtained by changing temperature T_{J} by step width ΔT_{J} as a new candidate value of temperature T_{J}. In the case of FIGS. 3A and 3B, step width ΔT_{J} of temperature T_{J} is set to 0.1° C. in step S104, and thus, temperature T_{J} is updated to a value that is larger by 0.1° C. than temperature T_{J} at a present time point.

In next step S111, processing device 105 specifies a value of current I_{C} (V_{CE}, T_{J}) from the I_{C}−V_{CE} characteristic at updated temperature T_{J} based on the measurement value of first potential difference V_{CE}. This processing means that current I_{C} at specified first potential difference V_{CE} is read from the curved line indicating the I_{C}−V_{CE} characteristic at updated temperature T_{J}.

In next step S112, processing device 105 specifies a value of current I_{C} (V_{EE}, T_{J}) from the I_{C}−V_{EE} characteristic at updated temperature T_{J} based on the measurement value of second potential difference V_{EE}. This processing means that current I_{C} at specified second potential difference V_{EE} is read from the straight line indicating the I_{C}−V_{EE} characteristic at updated temperature T_{J}. Either step S111 or step S112 may be performed first, or steps S111 and S112 may be performed simultaneously.

In next step S113, processing device 105 calculates a difference I_{C} (V_{CE}, T_{J})−I_{C} (V_{EE}, T_{J}) between the two current values specified in steps S111 and S112, and substitutes the calculation result into ΔI_{C}(1). ΔI_{C}(1) refers to, in the case of repeatedly calculating a difference between two current values I_{C} while changing the candidate value of temperature T_{J}, a difference between the current values calculated with respect to a currently set candidate value of temperature T_{J}.

In next step S114, processing device 105 determines whether difference ΔI_{C}(1) between two current values I_{C} calculated in step S113 is equal to 0. When ΔI_{C}(1)=0 is satisfied (YES in step S114), the value of current I_{C} obtained from first potential difference V_{CE} matches the value of current I_{C} obtained from second potential difference V_{EE}. Therefore, in next step S121, processing device 105 outputs present I_{C} (V_{CE}, T_{J}) as the current value and outputs present T_{J} as the temperature, and then, ends the process.

In contrast, when ΔI_{C}(1)=0 is not satisfied (NO in step S114), processing device 105 moves the process to step S115. In step S115, processing device 105 obtains (ΔI_{C}(0)/abs(ΔI_{C}(0)×(ΔI_{C}(1)/abs(ΔI_{C}(1) using difference ΔI_{C}(0) between current values I_{C} calculated with respect to the previously set candidate value of temperature T_{J} and difference ΔI_{C}(1) between current values I_{C} calculated with respect to the currently set candidate value of temperature T_{J}, and substitutes this into a first determination value S. When a sign of difference ΔI_{C}(0) between current values I_{C} calculated with respect to the previously set candidate value of temperature T_{J} and a sign of difference ΔI_{C}(1) between current values I_{C} calculated with respect to the currently set candidate value of temperature T_{J} are reversed, S=−1 is satisfied. When the sings are not reversed, S=1 is satisfied.

A calculation formula for first determination value S will be described in a little more detail. abs(x) is a function for obtaining an absolute value of x. ΔI_{C}(0)/abs (ΔI_{C}(0)) means that a value of ΔI_{C}(0) is divided by an absolute value thereof. Therefore, ΔI_{C}(0)/abs (ΔI_{C}(0)) is 1 when difference ΔI_{C}(0) between the previous current values is positive, and −1 when difference ΔI_{C}(0) between the previous current values is negative. Similarly, ΔI_{C}(1)/abs (ΔI_{C}(1)) is 1 when difference ΔI_{C}(1) between the present current values is positive, and −1 when difference ΔI_{C}(1) between the present current values is negative. A result obtained by multiplying these is substituted into S. Therefore, when difference ΔI_{C}(0) between the previous current values and difference ΔI_{C}(1) between the present current values are both 1 or both −1, S=1 is satisfied. When one of difference ΔI_{C}(0) between the previous current values and difference ΔI_{C}(1) between the present current values is 1 and the other is −1, S=−1 is satisfied.

In summary, when difference ΔI_{C} between the current values at the previously set value of temperature T_{J} and difference ΔI_{C} between the current values at the currently set value of temperature T_{J} are reversed in terms of whether it is positive or negative (i.e., the sign), S=−1 is satisfied. The reversal of the sign of difference ΔI_{C} between the current values means that current I_{C} obtained from first potential difference V_{CE} is smaller than current I_{C} obtained from second potential difference V_{EE} at the currently set value of temperature T_{J} although current I_{C} obtained from first potential difference V_{CE} is larger than current I_{C} obtained from second potential difference V_{EE} at the previously set value of temperature T_{J}, or means that I_{C} obtained from first potential difference V_{CE} is larger than current I_{C} obtained from second potential difference V_{EE} at the currently set value of temperature T_{J} although I_{C} obtained from first potential difference V_{CE} is smaller than current I_{C} obtained from second potential difference V_{EE} at the previously set value of temperature T_{J}. The fact that the magnitude relationship of I_{C} is reversed simply by changing temperature T_{J} by step width ΔT_{J} means that temperature T_{J} is updated across an optimum value (value to be obtained). This can also be confirmed from the fact that the sign of difference ΔI_{C} between the current values when temperature T_{J}=25° C. and the sign of difference ΔI_{C} between the current values when temperature T_{J}=125° C. are reversed in FIG. 2. Here, when step width ΔT_{J} of temperature T_{J} has a sufficiently small value, the currently set candidate value of temperature T_{J} may be regarded as an optimum value of temperature T_{J}.

Thus, in next step S116, processing device 105 determines whether first determination value S calculated in step S115 is equal to −1. When S=−1 is satisfied (YES in step S116), processing device 105 moves the process to step S121. In step S121, processing device 105 outputs present I_{C} (V_{CE}, T_{J}) as the current value and outputs present T_{J} as the temperature, and then, ends the process.

In contrast, when S=−1 is not satisfied (NO in step S116), S=1 is satisfied. This means that difference ΔI_{C} between the current values is positive both at the previously set value of temperature T_{J} and at the currently set value of temperature T_{J} (ΔI_{C}(0)>0 and ΔI_{C}(1)>0), or difference ΔI_{C} between the current values is negative both at the previously set value of temperature T_{J} and at the currently set value of temperature T_{J} (ΔI_{C}(0)<0 and ΔI_{C}(1)<0). That is, current I_{C} obtained from first potential difference V_{CE} remains larger than current I_{C} obtained from second potential difference V_{EE}, or current I_{C} obtained from first potential difference V_{CE} remains smaller than current I_{C} obtained from second potential difference V_{EE}. Since temperature T_{J} does not change across the optimum value, temperature T_{J} needs to be further changed by ΔT_{J}.

Here, it is necessary to determine whether a direction of changing the set value of temperature T_{J} is correct. A decrease in difference ΔI_{C} between the current values caused by the change from the previously set value of temperature T_{J} to the currently set value of temperature T_{J} means that temperature T_{J} is changed in a correct direction. Conversely, an increase in difference ΔI_{C} between the current values caused by the change from the previously set value of temperature T_{J} to the currently set value of temperature T_{J} means that the set value of temperature T_{J} is changed in a wrong direction.

Thus, in next step S117, processing device 105 calculates a second determination value D for determining whether the direction of changing temperature Ty is correct. A product of ΔI_{C}(0)/abs (ΔI_{C}(0) and (ΔI_{C}(0)−ΔI_{C}(1)/abs (ΔI_{C}(0)−ΔI_{C}(1)) is substituted into second determination value D.

First, ΔI_{C}(0)/abs (ΔI_{C}(0)) indicates the sign of difference ΔI_{C}(0) between the current values at the previously set value of temperature T_{J} as described above. Next, ΔI_{C}(0)−ΔI_{C}(1) indicates a difference between difference ΔI_{C}(0) between the current values at the previously set value of temperature T_{J} and difference ΔI_{C}(1) between the current values at the currently set value of temperature T_{J}. In the following description, this difference will be referred to as a residual. Since (ΔI_{C}(0)−ΔI_{C}(1))/abs (ΔI_{C}(0)−ΔI_{C}(1)) is obtained by dividing this residual by an absolute value thereof, (ΔI_{C}(0)−ΔI_{C}(1)/abs (ΔI_{C}(0)−ΔI_{C}(1)) is 1 when the sign of the residual is positive, and −1 when the sign of the residual is negative.

When the sign of the residual is positive, ΔI_{C}(0)>ΔI_{C}(1) is satisfied, which means that difference ΔI_{C}(1) between the current values at the currently set value of temperature T_{J} is smaller than difference ΔI_{C}(0) between the current values at the previously set value of temperature T_{J}. It should be noted that “smaller” here means smaller in value, not in absolute value. Therefore, when difference ΔI_{C}(0) between the current values at the previously set value of temperature T_{J} and difference ΔI_{C}(1) between the current values at the currently set value of temperature T_{J} are both positive, the absolute value of difference ΔI_{C}(1) between the present current values is smaller than the absolute value of difference ΔI_{C}(0) between the previous current values. Conversely, when difference ΔI_{C}(0) between the current values at the previously set value of temperature T_{J} and difference ΔI_{C}(1) between the current values at the currently set value of temperature T_{J} are both negative, the absolute value of difference ΔI_{C}(1) between the present current values is larger than the absolute value of difference ΔI_{C}(0) between the previous current values.

In contrast, when the sign of the residual is negative, ΔI_{C}(0)<ΔI_{C}(1) is satisfied, which means that difference ΔI_{C}(1) between the current values at the currently set value of temperature T_{J} is larger than difference ΔI_{C}(0) between the current values at the previously set value of temperature T_{J}. Therefore, when difference ΔI_{C}(0) between the current values at the previously set value of temperature T_{J} and difference ΔI_{C}(1) between the current values at the currently set value of temperature T_{J} are both positive, the absolute value of difference ΔI_{C}(1) between the present current values is larger than the absolute value of difference ΔI_{C}(0) between the previous current values. Conversely, when difference ΔI_{C}(0) between the current values at the previously set value of temperature T_{J} and difference ΔI_{C}(1) between the current values at the currently set value of temperature T_{J} are both negative, the absolute value of difference ΔI_{C}(1) between the present current values is smaller than the absolute value of difference ΔI_{C}(0) between the previous current values.

In summary, since the product of the sign of difference ΔI_{C}(0) between the current values at the previously set value of temperature T_{J} and the sign of the residual (ΔI_{C}(0)−ΔI_{C}(1)) is substituted into second determination value D, the following four cases occur.
(i) The case in which difference ΔI_{C}(0) between the current values at the previously set value of temperature T_{J} is positive and the currently calculated residual is positive. In this case, difference ΔI_{C} between the current values is positive both at the previously set value of temperature T_{J} and at the currently set value of temperature T_{J}, and the absolute value of difference ΔI_{C}(1) between the current values at the currently set value of temperature T_{J} is smaller than the absolute value of difference ΔI_{C}(0) between the current values at the previously set value of temperature T_{J}. The value of second determination value D in this case is D=1×1=1.
(ii) The case in which difference ΔI_{C}(0) between the current values at the previously set value of temperature T_{J} is positive and the currently calculated residual is negative. In this case, difference ΔI_{C} between the current values is positive both at the previously set value of temperature T_{J} and at the currently set value of temperature T_{J}, and the absolute value of difference ΔI_{C}(1) between the current values at the currently set value of temperature T_{J} is larger than the absolute value of difference ΔI_{C}(0) between the current values at the previously set value of temperature T_{J}. The value of second determination value D in this case is D=1×−1=−1.
(iii) The case in which difference ΔI_{C}(0) between the current values at the previously set value of temperature T_{J} is negative and the currently calculated residual is positive. In this case, difference ΔI_{C} between the current values is negative both at the previously set value of temperature T_{J} and at the currently set value of temperature T_{J}, and the absolute value of difference ΔI_{C}(1) between the current values at the currently set value of temperature T_{J} is larger than the absolute value of difference ΔI_{C}(0) between the current values at the previously set value of temperature T_{J}. The value of second determination value D in this case is D=−1×1=−1.
(iv) The case in which difference ΔI_{C}(0) between the current values at the previously set value of temperature T_{J} is negative and the currently calculated residual is negative. In this case, difference ΔI_{C} between the current values is negative both at the previously set value of temperature T_{J} and at the currently set value of temperature T_{J}, and the absolute value of difference ΔI_{C}(1) between the current values at the currently set value of temperature T_{J} is smaller than the absolute value of difference ΔI_{C}(0) between the current values at the previously set value of temperature T_{J}. The value of second determination value D in this case is D=−1×−1=1.

It can be seen from the foregoing that D=1 is satisfied when the absolute value of difference ΔI_{C}(1) between the current values at the currently set value of temperature T_{J} is smaller than the absolute value of difference ΔI_{C}(0) between the current values at the previously set value of temperature T_{J}, and D=−1 is otherwise satisfied. That is, D=1 is satisfied when temperature T_{J} is updated in the correct direction, and D=−1 is satisfied when temperature T_{J} is updated in the wrong direction.

Thus, in next step S118, processing device 105 determines whether second determination value D is equal to 1. When D=1 is satisfied (YES in step S118), processing device 105 moves the process to step S120 without changing step width ΔT_{J} of the temperature. In contrast, when D=−1 is satisfied (NO in step S118), processing device 105 substitutes-ΔT_{J} into ΔT_{J} in order to reverse the sign of step width ΔT_{J} of the temperature in next step S119.

In next step S120, processing device 105 substitutes the value of difference ΔI_{C}(1) between the current values at the currently set value of temperature T_{J} into difference ΔI_{C}(0) between the current values at the previously set value of temperature Ti, and updates the value of difference ΔI_{C}(0) between the current values at the previously set value of temperature T_{J}. Thereafter, processing device 105 returns the process to step S110, changes temperature T_{J} to temperature T_{J}+ΔT_{J} by changing temperature T_{J} by step width ΔT_{J}, and again performs the processing in the subsequent steps. By performing such repetitive calculation, there eventually arises such an event that difference ΔI_{C} between the current values becomes 0 (YES in step S114) or the sign of difference ΔI_{C} between the current values at the previously set value of temperature T_{J} and the sign of difference ΔI_{C} between the current values at the currently set value of temperature T_{J} are reversed (YES in step S116). As a result, current I_{C} and temperature T_{J} as the optimum estimates are finally obtained (step S121).

In the above-described process flow, initial value T_{J}(0) of temperature T_{J} set in step S103 and step width ΔT_{J} of the temperature change set in step S104 are given by way of example and can be changed as necessary. For example, it is useful to set the initial value of temperature T_{J} to a temperature around an expected temperature in order to reduce the number of times of calculation. In addition, it is also useful to decrease step width ΔT_{J} of the temperature change in order to increase the calculation accuracy, or to increase step width ΔT_{J} of the temperature change as appropriate in order to reduce the number of times of calculation.

As each of the first relationship and the second relationship stored in storage device 104, detailed data can be stored as necessary, or representative data can be stored.

For example, by storing the detailed data, e.g., the detailed data obtained by changing temperature T_{J} at a step width of 0.1° C. and recording temperature T_{J} over a wide temperature range, in storage device 104, accurate current I_{C} at temperature T_{J} can be specified and the measurement accuracy can be improved, although the data volume increases. By increasing the step width of temperature T_{J} and reducing the data volume, the cost of storage device 104 can be reduced. In this case, the data at temperature T_{J} that is not stored (corresponding to a trace in FIG. 2) can be calculated by interpolation from traces on both sides of this trace, and current I_{C} can be specified using the interpolated trace. Linear interpolation in which only two traces on both sides are used, spline interpolation in which three or more traces are used for more accurate interpolation, or the like can be selected as appropriate as a method for interpolation.

A data interval of each of first potential difference V_{CE} and second potential difference V_{EE} can also be arbitrarily selected in consideration of the storage capacity and the accuracy. When the traces are prepared at small voltage intervals, the accurate traces can be obtained, although the data volume increases. When the traces are prepared at large voltage intervals and the data is obtained by interpolation, the data volume can be reduced and the storage capacity can be reduced. As a method for interpolation in this case as well, linear interpolation, spline interpolation or the like can be freely selected in consideration of the calculation speed and the computation accuracy.

By performing calculation in accordance with the procedure shown in FIGS. 3A and 3B as described above, the estimate of specified main current I_{C} is output as current information 106 and the estimate of specified temperature T_{J} is output as temperature information 107. By comparing these current information 106 and temperature information 107 with the defined values kept separately in the memory, a present operation state of semiconductor device 1 can be grasped. As a result, an operation state of semiconductor device 1 or a power conversion device such as an inverter including this semiconductor device 1 can be grasped, and a malfunction of a system caused by a malfunction of semiconductor device 1 or the power conversion device can be prevented in advance.

Although not shown in FIG. 1A, a terminal unit that takes out current information 106 and temperature information 107, and a determination unit that determines the state of semiconductor device 1 or the power conversion device based on taken out current information 106 and temperature information 107 may be provided. The determination unit can feed the determination information back to gate driver 8, thereby performing control in accordance with the state of semiconductor device 1 or the power conversion device. Hardware constituting the determination unit may be configured based on a microcomputer including a CPU and a memory, may be configured using an FPGA, or may be configured by dedicated circuitry. Alternatively, the determination unit may be configured by two or more combinations of these components.

### Effects of First Embodiment

As described above, in semiconductor characteristics measuring apparatus 101 according to the first embodiment, main current I_{C} and temperature T_{J} can be simultaneously measured simply by measuring the two potential differences of semiconductor device 1. A current sensor and a temperature sensor are unnecessary, power semiconductor element 2 does not require a sense cell, and a complicated and expensive device such as a voltage controller, a gate voltage measuring device or a switching speed measuring device is also unnecessary. Thus, current I_{C} and temperature T_{J} of semiconductor device 1 can be measured at lower cost, which results in such a remarkable effect that the soundness of semiconductor device 1 can be ensured at low cost.

Furthermore, when temperature T_{J} and current I_{C} of semiconductor device 1 are estimated using semiconductor characteristics measuring apparatus 101, the soundness of a power conversion device such as an inverter device including semiconductor device 1 can be easily checked by determining whether a voltage of each portion of this power conversion device matches a value calculated from the above-described estimates of temperature T_{J} and current I_{C}. In addition, since the soundness of semiconductor device 1 can be easily checked, there is no need to manufacture the power conversion device with an unnecessarily large performance margin, which can lead to a reduction in cost.

In addition, semiconductor characteristics measuring apparatus 101 only measures a voltage between terminals provided in an existing device including semiconductor device 1. Therefore, semiconductor characteristics measuring apparatus 101 can be not only incorporated into a new device but also retrofitted to an existing device, which leads to a wide application range.

### Second Embodiment

In the first embodiment, the IGBT is used as power semiconductor element 2 built into semiconductor device 1. In a second embodiment, description will be given of the case in which a metal-oxide-semiconductor field effect transistor (MOSFET) is used as a power semiconductor element 2A built into a semiconductor device 1A.

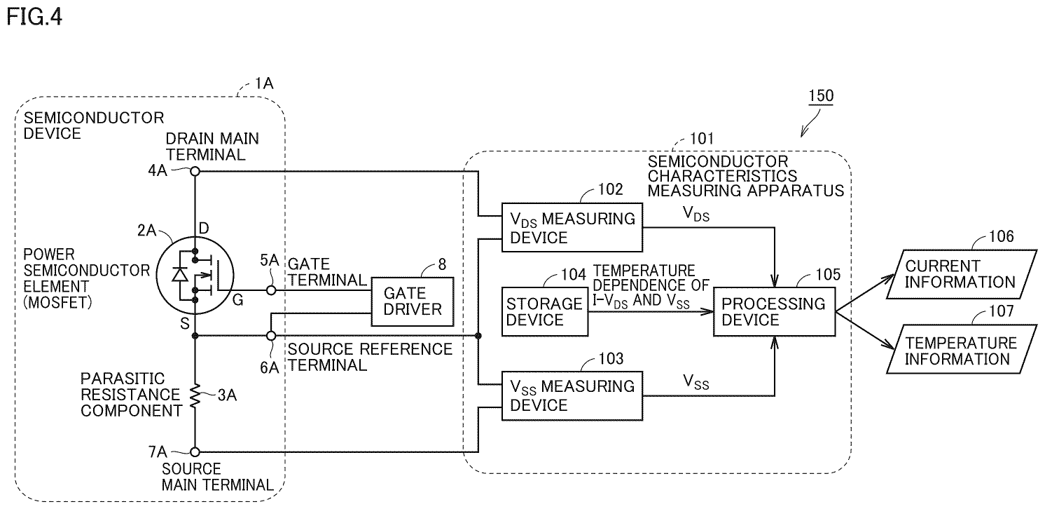

FIG. 4 is a configuration diagram of semiconductor characteristics measuring apparatus 101 according to the second embodiment. FIG. 4 shows semiconductor device 1A to be measured by semiconductor characteristics measuring apparatus 101.

Semiconductor device 1A includes an MOSFET serving as power semiconductor element 2A, a drain main terminal 4A, a gate terminal 5A, a source reference terminal 6A, and a source main terminal 7A. Drain main terminal 4A is connected to a drain electrode D of the MOSFET, gate terminal 5A is connected to a gate electrode G of the MOSFET, and source main terminal 7A is connected to a source electrode S of the MOSFET. A main current (i.e., a drain current I_{D}) of power semiconductor element 2A flows through drain main terminal 4A and source main terminal 7A. Although source reference terminal 6A is connected to source electrode S, the main current does not flow through source reference terminal 6A. A parasitic resistance component 3A is present in a wire between source main terminal 7A and source electrode S. Gate driver 8 is connected between gate terminal 5A and source reference terminal 6A.

Since the configuration of semiconductor characteristics measuring apparatus 101 shown in FIG. 4 is similar to the configuration shown in FIG. 1A, the same or corresponding portions are denoted by the same reference characters and detailed description will not be repeated. However, since the MOSFET is used as the power semiconductor element instead of the IGBT, a part of the designations are changed. Specifically, the collector of the IGBT is replaced by the drain of the MOSFET, and the emitter of the IGBT is replaced by the source of the MOSFET. In accordance with this, first potential difference V_{CE} is denoted as V_{DS}, second potential difference V_{EE} is denoted as V_{SS}, and main current I_{C} is denoted as I_{D}.

According to the notation above, first potential difference measuring device 102 of semiconductor characteristics measuring apparatus 101 shown in FIG. 4 measures first potential difference V_{DS} between drain main terminal 4A and source reference terminal 6A. Second potential difference measuring device 103 measures second potential difference V_{SS} between source reference terminal 6A and source main terminal 7A. Storage device 104 stores a first relationship among preliminarily measured or calculated first potential difference V_{DS}, main current I_{D} and junction temperature T_{J}, and a second relationship among preliminarily measured or calculated second potential difference V_{SS}, main current I_{D} and junction temperature T_{J}. Processing device 105 specifies main current I_{D} and temperature T_{J} using measured first potential difference V_{DS} and second potential difference V_{SS}, and the first relationship and the second relationship stored in storage device 104, and outputs main current I_{D} and temperature T_{J} as current information 106 and temperature information 107.

As described with reference to FIG. 1B, first potential difference measuring device 102 may measure a potential difference between drain main terminal 4A and source main terminal 7A. Generally, first potential difference measuring device 102 measures first potential difference V_{DS} based on a potential difference between two connection terminals connected to a first main electrode and a second main electrode, respectively, of a plurality of connection terminals provided in semiconductor device 1A.

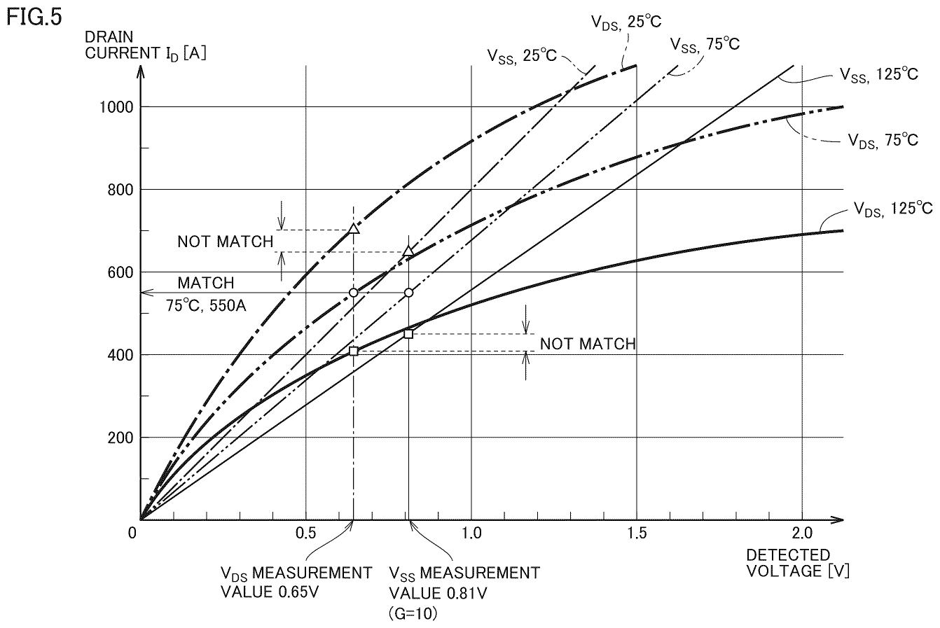

FIG. 5 is a diagram for illustrating an operation principle of semiconductor characteristics measuring apparatus 101 shown in FIG. 4. In FIG. 5, the first relationship and the second relationship stored in storage device 104 of semiconductor characteristics measuring apparatus 101 are shown in the form of graph. The first relationship is a relationship among first potential difference V_{DS}, current I_{D} and temperature T_{J}. The second relationship is a relationship among second potential difference V_{SS}, current I_{D} and temperature T_{J}.

As shown in FIG. 5, a trace indicating a I_{D}−V_{DS} characteristic, which is the first relationship in the case of the MOSFET, has non-linearity different from that of the trace indicating the I_{C}−V_{CE} characteristic in the case of the IGBT. This is because the operation principle of the MOSFET is different from that of the IGBT. Even in the case of the MOSFET, a I_{D}−V_{SS} characteristic reflects an electrical resistance of the bonding wires made of aluminum, and thus, the trace thereof has linearity similar to that of the IGBT.

As described above, the first relationship and the second relationship are two types of relationships that are different in linearity. Therefore, even in the second embodiment, main current I_{D} and temperature T_{J} of semiconductor device 1 can be simultaneously obtained in accordance with an operation principle and process contents that are basically similar to those in the first embodiment. Specifically, the collector in the process contents in the first embodiment is replaced by the drain and the emitter in the process contents in the first embodiment is replaced by the source. However, when an absolute value of current I_{D} is relatively small, an exceptional process is required. This exceptional process will be described in a third embodiment.

As shown as an example in FIG. 5, a measurement value of first potential difference V_{DS} is assumed to be 0.65 V and a measurement value of second potential difference V_{SS} (gain G=10) is assumed to be 0.81 V. In this case, junction temperature T_{J} is determined as 75° C. from a temperature when a value of current I_{D} obtained from first potential difference V_{DS} matches a value of current I_{D} obtained from second potential difference V_{SS}. In addition, since the matching value of current I_{D} is 550 A, processing device 105 outputs 550 A as current information 106 and outputs 75° C. as temperature information 107.

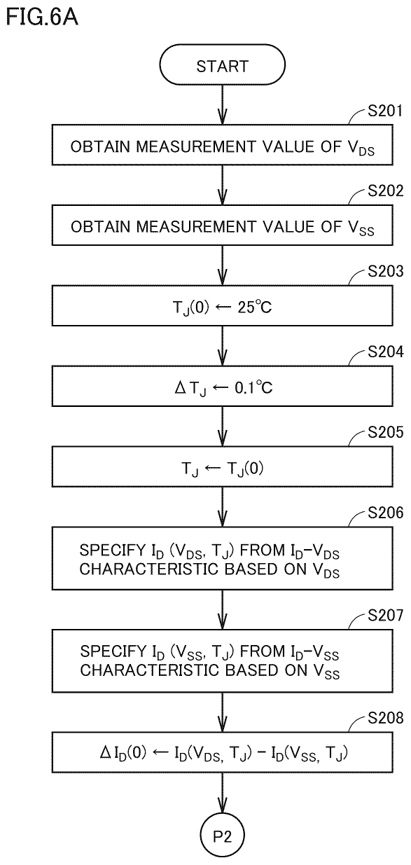

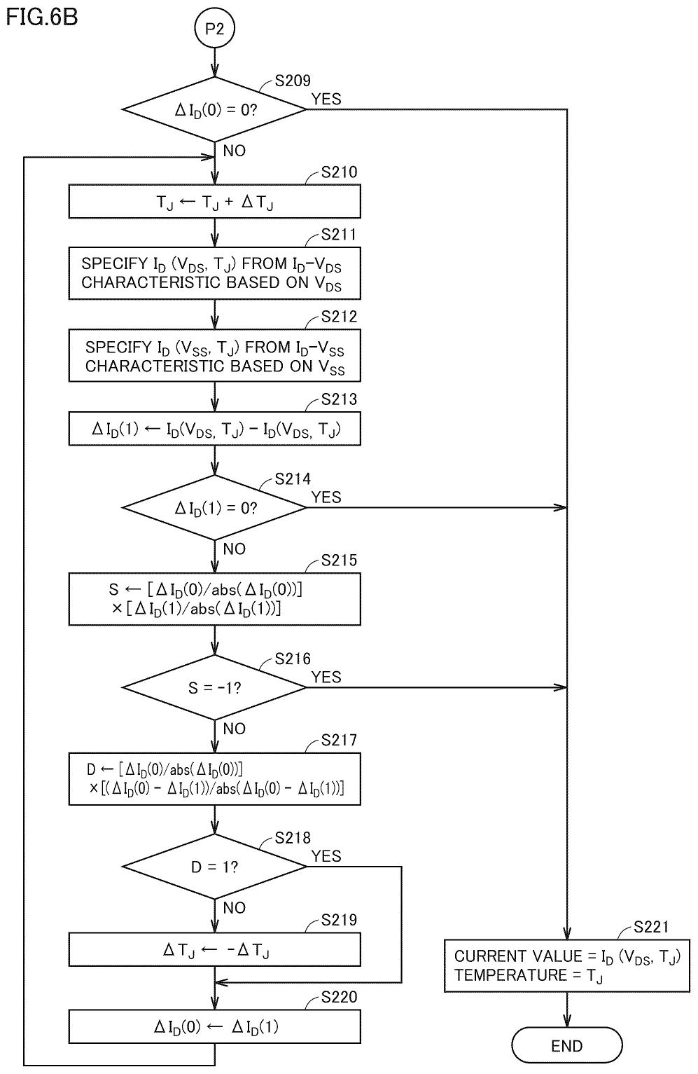

FIGS. 6A and 6B are flowcharts each showing a process procedure performed by processing device 105 of semiconductor characteristics measuring apparatus 101 shown in FIG. 4.

Since the process procedure in each of the flowcharts shown in FIGS. 6A and 6B is similar to the process procedure in each of the flowcharts shown in FIGS. 3A and 3B, detailed description will not be repeated. Steps S201 to S221 in FIGS. 6A and 6B correspond to steps S101 to S121 in FIGS. 3A and 3B, respectively. However, in FIGS. 6A and 6B, V_{CE}, V_{EE} and I_{C} in FIGS. 3A and 3B are replaced by V_{DS}, V_{SS} and I_{D}, respectively.

As described above, basically similarly to the semiconductor characteristics measuring apparatus according to the first embodiment, main current I_{D} and temperature T_{J} can be simultaneously measured simply by measuring the two potential differences of semiconductor device 1A in the semiconductor characteristics measuring apparatus according to the second embodiment designed for the MOSFET as well. A current sensor and a temperature sensor are unnecessary, power semiconductor element 2A does not require a sense cell, and a complicated and expensive device such as a voltage controller, a gate voltage measuring device or a switching speed measuring device is also unnecessary. Thus, current I_{D} and temperature T_{J} of semiconductor device 1A can be measured at lower cost, which results in such a remarkable effect that the soundness of semiconductor device 1A can be ensured at low cost.

### Third Embodiment

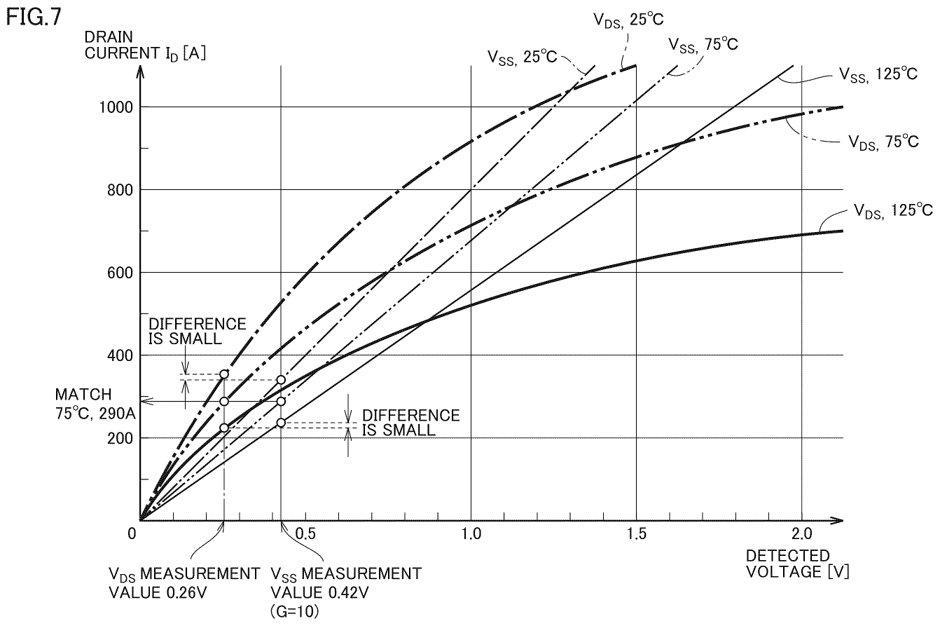

When power semiconductor element 2A built into semiconductor device 1A is the MOSFET, the I_{D}−V_{DS} characteristic has gentle non-linearity similar to a straight line passing through the origin in a range where the absolute value of current I_{D} is relatively small, and thus, the I_{D}−V_{DS} characteristic is similar to the linearity of the I_{D}−V_{SS} characteristic. This makes determination of temperature Ta difficult, and an estimation error of temperature T_{J} and an estimation error of current I_{D} may become larger. This will be described below with reference to FIG. 7.

FIG. 7 is a diagram for illustrating an operation principle of a semiconductor characteristics measuring apparatus according to a third embodiment. Similarly to the case shown in FIG. 5, the first relationship and the second relationship in the case of the MOSFET are shown in the form of graph in FIG. 7.

As shown as an example in FIG. 7, a measurement value of first potential difference V_{DS} is assumed to be 0.26 V, and a measurement value of second potential difference V_{SS} (gain G=10) is assumed to be 0.42 V. In this case, temperature T_{J} can be estimated as 75° C. and a value of current I_{D} can be estimated as 290 A by using the same method as that in the first and second embodiments. However, even when temperature T_{J} deviates from 75° C., which is an optimum temperature, a difference ΔI_{D} between a current estimate based on the measurement value of first potential difference V_{DS} and a current estimate based on the measurement value of second potential difference V_{SS} is small. Therefore, temperature T_{J} may be estimated incorrectly. Incorrect determination of temperature T_{J} leads to incorrect determination of the value of current I_{D}.

Thus, the semiconductor characteristics measuring apparatus according to the third embodiment performs temperature estimation only in a range where the measurement value of first potential difference V_{DS} is equal to or more than a certain threshold value, which is a range where the non-linearity of first potential difference V_{DS} is high. When first potential difference V_{DS} is less than the threshold value, immediately preceding estimated temperature T_{J} is used as an estimate of temperature Ti. This process is based on the fact that a change in temperature T_{J} is gentler than a change in current I_{D}. As a result, even when current I_{D} flowing through the MOSFET is relatively small, current I_{D} and temperature T_{J} can be estimated with a reduced error.

First potential difference V_{DS} serving as the above-described threshold value can be predetermined in accordance with the accuracy of processing device 105 used. For example, when the accuracy of processing device 105 used is low, first potential difference V_{DS} serving as the threshold value can be set to a relatively large value. When the accuracy of processing device 105 is high, first potential difference V_{DS} serving as the threshold value can be set to a relatively small value.

For example, the measurement value of first potential difference V_{DS} is assumed to be 0.26 V as in FIG. 7. Second potential difference V_{SS} (G=10) showing the same current value when temperature T_{J} is 75° C. is 0.42 V. Difference ΔI_{D} between the current values at 125° C. displaced upward by 50° C. from temperature T_{J} of 75° C., and difference ΔI_{D} between current values I_{D} at 25° C. displaced downward by 50° C. from temperature T_{J} of 75° C. are calculated. Whether 0.26 V should be set as the threshold value may be determined based on whether these differences ΔI_{D} between the current values are acceptable relative to the accuracy of processing device 105.

As described above, temperature estimation and current estimation are performed when the measurement value of first potential difference V_{DS} is equal to or more than the predetermined threshold value, and the immediately preceding measurement value is used as estimated temperature T_{J} when first potential difference V_{DS} is less than the threshold value. Therefore, an error can be suppressed.

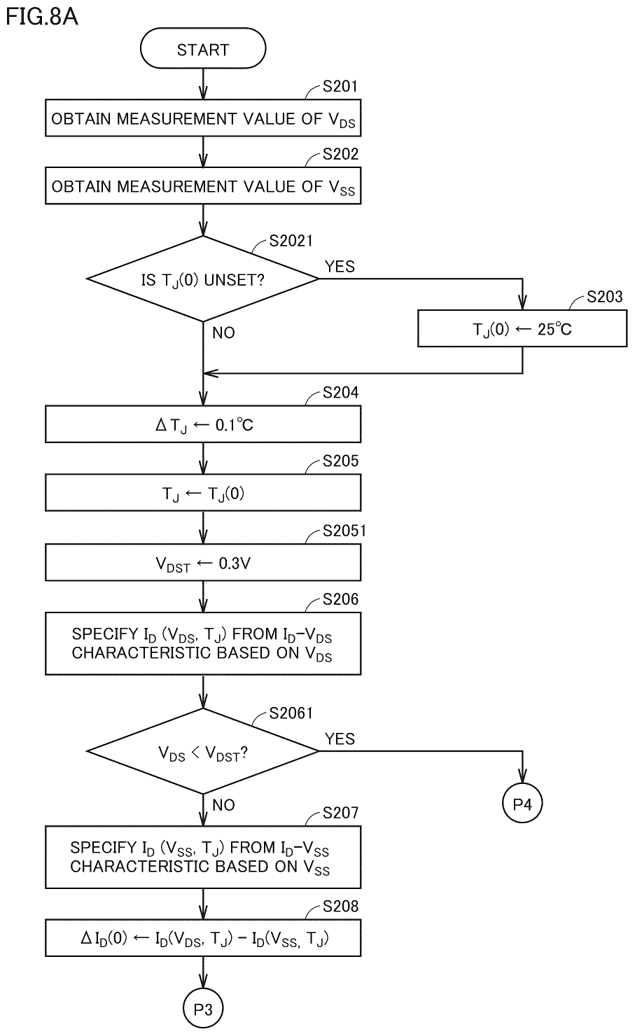

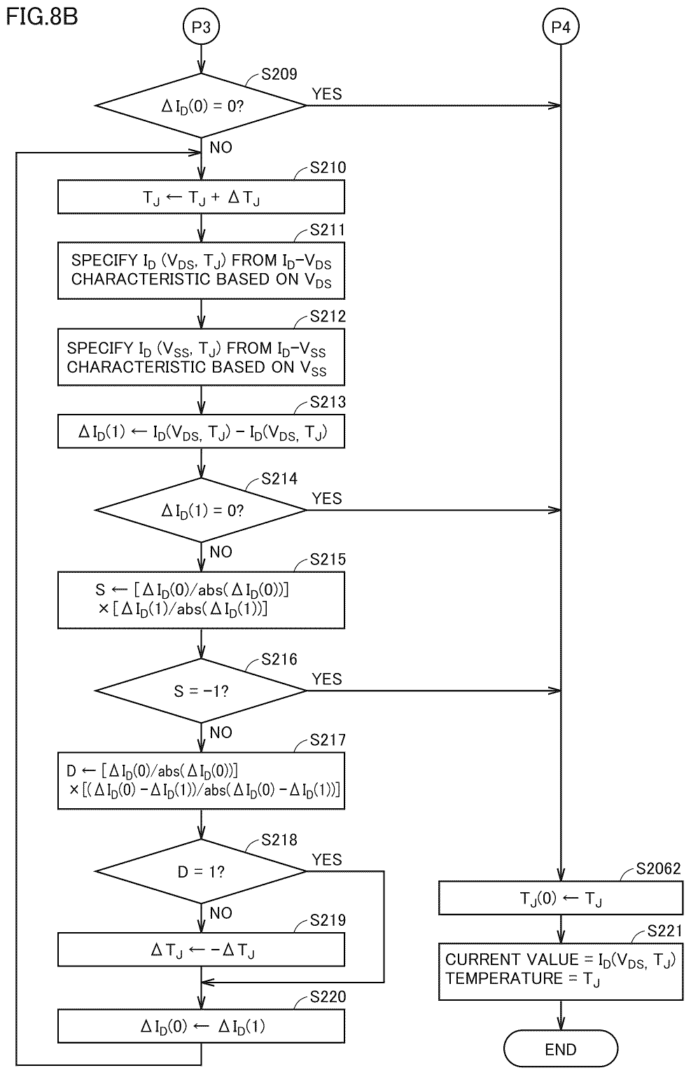

FIGS. 8A and 8B are flowcharts each showing the operation of the processing device of the semiconductor characteristics measuring apparatus according to the third embodiment. In the flowcharts shown in FIGS. 8A and 8B, steps S2021, S2051, S2061, and S2062 are further added to steps S201 to S221 in the flowcharts shown in FIGS. 6A and 6B. The added steps will be described below and description of the same steps as steps S201 to S221 shown in FIGS. 6A and 6B (i.e., the steps corresponding to steps S101 to S121 shown in FIGS. 3A and 3B) will not be repeated.

Step S2021 is performed before step S203. In step S2021, processing device 105 determines whether initial value T_{J}(0) of temperature T_{J} is unset. When initial value T_{J}(0) of temperature T_{J} is unset (YES in step S203), processing device 105 sets the initial value to, for example, 25° C. in next step S203.

In contrast, when initial value T_{J}(0) of temperature T_{J} has already been set (NO in step S203), processing device 105 moves the process to step S204, using the already set initial value. Here, a previously output estimate of temperature T_{J} is set as initial value T_{J}(0) in step S2062 described below.

Step S2051 is performed simultaneously with, or before or after steps S2021, S204 and S205. In step S2051, processing device 105 sets 0.3 V as threshold value V_{DST} of first potential difference V_{DS}, for example.

Step S2061 is performed after step S206. In step S2061, processing device 105 determines whether first potential difference V_{DS} obtained in step S201 is smaller than threshold value V_{DST}.

When first potential difference V_{DS} is smaller than threshold value V_{DST} (YES in step S105), processing device 105 moves the process to steps S2062 and S221. In this case, processing device 105 outputs, as final estimation results, temperature T_{J} having the initial value and current I_{D} specified based on first potential difference V_{DS} using this temperature (S221). In addition, processing device 105 stores output temperature T_{J} (i.e., previous value) as next initial value T_{J}(0) (S2062). As described above, when first potential difference V_{DS} is smaller than threshold value V_{DST}, the previous value is used as it is without estimating temperature T_{J}, and thus, an estimation error can be suppressed.

In contrast, when first potential difference V_{DS} is equal to or larger than threshold value V_{DST} (NO in step S105), processing device 105 moves the process to next step S207. The procedure in step S207 and the subsequent steps is similar to that in the second embodiment shown in FIGS. 6A and 6B. As described above, when first potential difference V_{DS} is equal to or larger than threshold value V_{DST}, the process procedure for estimating temperature T_{J} and current I_{D} is performed, and thus, the more accurate estimates of temperature T_{J} and current I_{D} can be output.

As described above, in the semiconductor characteristics measuring apparatus according to the third embodiment, even when current I_{D} is relatively small in estimating temperature T_{J} and current I_{D} of semiconductor device 1A including the MOSFET, an error can be suppressed.

### Fourth Embodiment

In power semiconductor element 2 used in semiconductor device 1, breakage or peeling of a part of many bonding wires connected to a surface of power semiconductor element 2 occurs, when power semiconductor element 2 is used for a long time. This may cause a sudden increase in measured first potential difference V_{CE} and second potential difference V_{EE}. Since this occurs instantaneously, the measurement values of first potential difference V_{DS} and second potential difference V_{EE} increase discontinuously as if the measurement values of first potential difference V_{CE} and second potential difference V_{EE} jump suddenly. This increase in measurement values is irreversible.

In a fourth embodiment, a semiconductor characteristics measuring apparatus that can deal with the above-described case is provided. Although the following technique will be described based on the semiconductor characteristics measuring apparatus according to the first embodiment, the following technique is also applicable to the semiconductor characteristics measuring apparatus designed for the MOSFET as in the second and third embodiments.

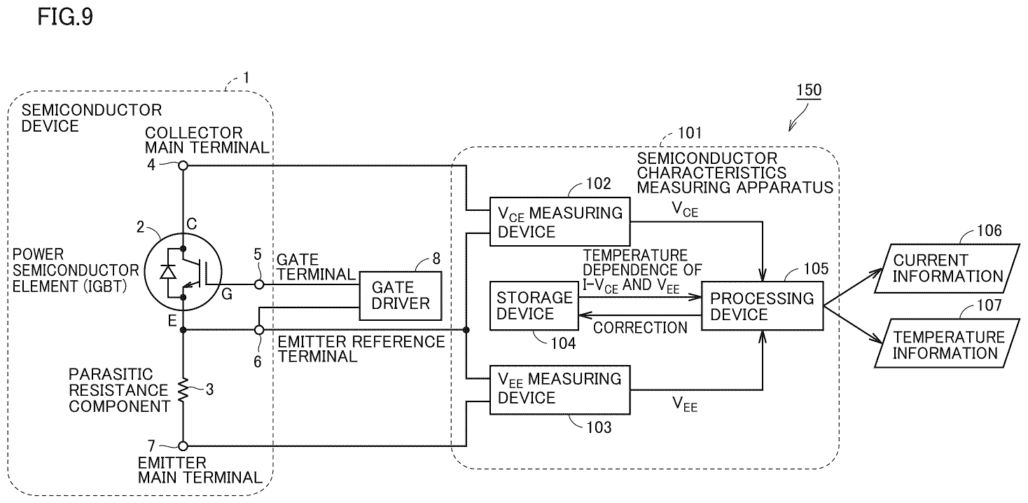

FIG. 9 is a configuration diagram of semiconductor characteristics measuring apparatus 101 according to the fourth embodiment. Semiconductor characteristics measuring apparatus 101 shown in FIG. 9 is different from semiconductor characteristics measuring apparatus 101 shown in FIG. 1A in that processing device 105 has the function of updating the data stored in storage device 104.

Specifically, processing device 105 monitors first potential difference V_{CE} measured by first potential difference measuring device 102 and second potential difference V_{EE} measured by second potential difference measuring device 103. When first potential difference V_{CE} and second potential difference V_{EE} increase suddenly, processing device 105 corrects, by a magnification rate of the increase, first potential difference V_{CE} in the data indicating the first relationship and second potential difference V_{EE} in the data indicating the second relationship that are stored in storage device 104.

When first potential difference V_{CE} and second potential difference V_{EE} are continuously measured with high frequency by first potential difference measuring device 102 and second potential difference measuring device 103, the magnitude of each jump can be measured. Since this voltage jump occurs instantaneously, the temperature and the current are regarded as remaining unchanged before and after the voltage jump.

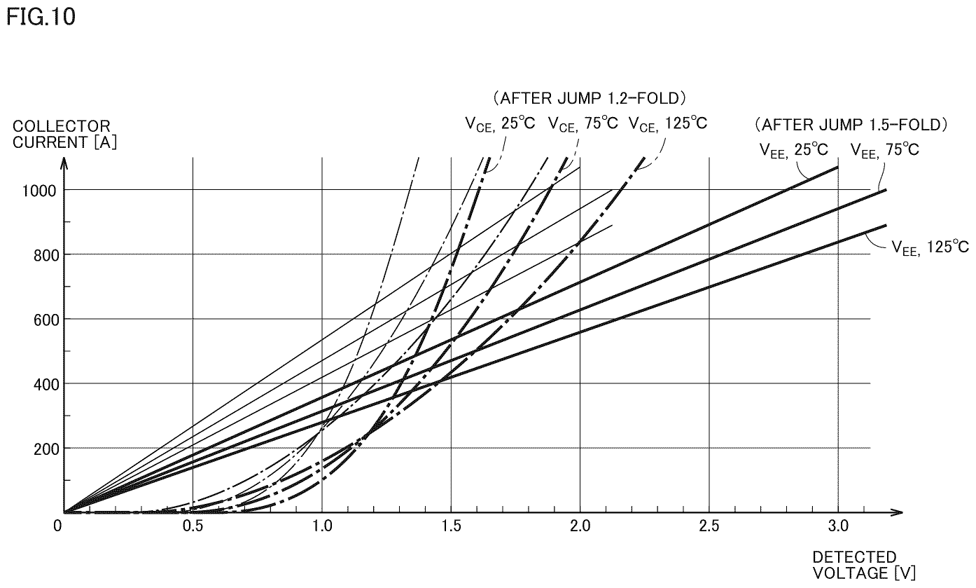

FIG. 10 is a diagram for illustrating an operation example of processing device 105 shown in FIG. 9. In FIG. 10, the I_{C}−V_{CE} characteristic stored in storage device 104 is indicated by a dash-dot line, and the I_{C}−V_{EE} characteristic is indicated by a solid line. In addition, the characteristics before first potential difference V_{CE} and second potential difference V_{EE} jump are indicated by thin lines, and the updated characteristics after the jump occurs are indicated by thick lines.

Since first potential difference V_{CE} and second potential difference V_{EE} jump due to peeling or breakage of the bonding wires, the increase in first potential difference V_{CE} and the increase in second potential difference V_{EE} always occur simultaneously. However, a magnification rate of the increase in first potential difference V_{CE} and a magnification rate of the increase in second potential difference V_{EE} may be somewhat different.

For example, it is assumed that first potential difference V_{CE} has jumped 1.2-fold and second potential difference V_{EE} has jumped 1.5-fold. In this case, as shown in FIG. 10, processing device 105 changes, by a factor of 1.2, the value of first potential difference V_{CE} at the same temperature and at the same current value in the data indicating the first relationship stored in storage device 104. Similarly, processing device 105 changes, by a factor of 1.5, the value of second potential difference V_{EE} at the same temperature and at the same current value in the data indicating the second relationship stored in storage device 104.

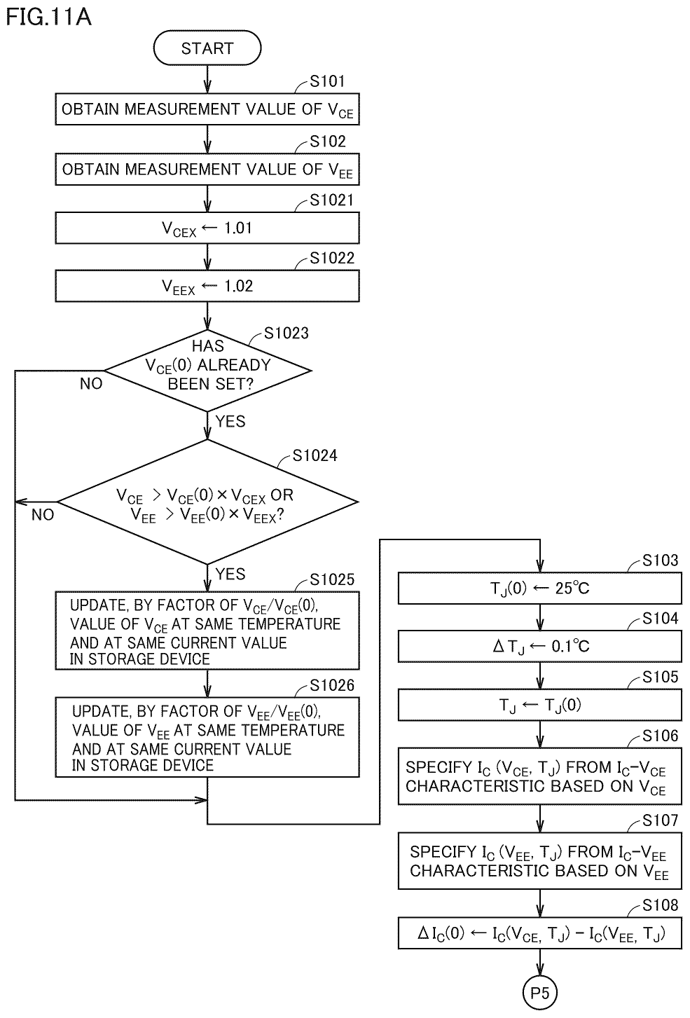

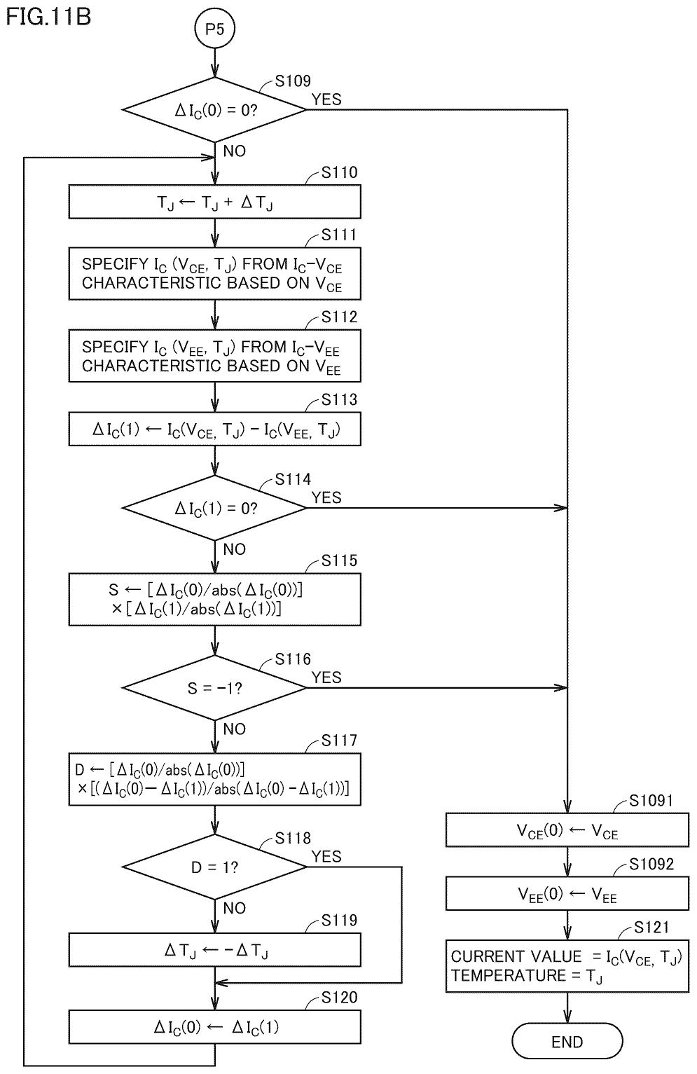

FIGS. 11A and 11B are flowcharts each showing a process procedure performed by processing device 105 of semiconductor characteristics measuring apparatus 101 shown in FIG. 9. In the flowcharts shown in FIGS. 11A and 11B, steps S1021 to S1026, S1091 and S1092 are further added to steps S101 to S121 in the flowcharts shown in FIGS. 3A and 3B. The added steps will be described below and description of the same steps as steps S101 to S121 in FIGS. 3A and 3B will not be repeated.

Steps S1021 to S1026 are performed after step S102. In steps S1021 and S1022, processing device 105 sets a threshold magnification rate V_{CEX} of a magnification rate of first potential difference V_{CE} to 1.01 and sets a threshold magnification rate V_{EEX} of second potential difference V_{EE} to 1.02, for example. Steps S1021 and S1022 may be performed simultaneously, or either step S1021 or step S1022 may be performed first.

In next step S1023, processing device 105 determines whether a previous measurement value V_{CE}(0) of first potential difference V_{CE} has already been set. Previous measurement value V_{CE}(0) of first potential difference V_{CE} and a previous measurement value V_{EE}(0) of second potential difference V_{EE} are set in steps S1091 and S1092. When previous measurement value V_{CE}(0) of first potential difference V_{CE} has not been set (NO in step S1023), processing device 105 moves the process to step S103. In step S103 and the subsequent steps, processing device 105 performs the process similar to that shown in FIGS. 3A and 3B.

In contrast, when previous measurement value V_{CE}(0) of first potential difference V_{CE} has already been set (YES in step S1023), processing device 105 determines whether a magnification rate of currently measured first potential difference V_{CE} with respect to previous measurement value V_{CE}(0) exceeds threshold magnification rate V_{CEX}, i.e., whether V_{CE}>V_{CE}(0)×V_{CEX} is satisfied, in next step S1024. Furthermore, processing device 105 determines whether a magnification rate of currently measured second potential difference V_{EE} with respect to previous measurement value V_{EE}(0) exceeds threshold magnification rate V_{EEX}, i.e., whether V_{EE}>V_{EE}(0)×V_{EEX} is satisfied.

When at least one of the determinations above is satisfied (YES in step S1024), processing device 105 moves the process to step S1025 and S1026. In step S1025, processing device 105 changes, by a factor of V_{CE}/V_{CE}(0), which is the observed magnification rate, the value of first potential difference V_{CE} at the same temperature and at the same current value in the data indicating the first relationship stored in storage device 104. In step S1026, processing device 105 changes, by a factor of V_{EE}/V_{EE}(0), which is the observed magnification rate, the value of second potential difference V_{EE} at the same temperature and at the same current value in the data indicating the second relationship stored in storage device 104. Either step S1025 or step S1026 may be performed first, or steps S1025 and S1026 may be performed simultaneously. Thereafter, processing device 105 moves the process to step S103.

In contrast, when both of the determinations in step S1024 are not satisfied (NO in step S1024), processing device 105 moves the process to step S103 without updating the data stored in storage device 104. In step S103 and the subsequent steps, processing device 105 performs the process similar to that shown in FIGS. 3A and 3B.

As described above, in the semiconductor characteristics measuring apparatus according to the fourth embodiment, even when the I_{C}−V_{CE} characteristic and the I_{C}−V_{EE} characteristic of the semiconductor device change suddenly due to peeling or breakage of the bonding wires connected to the power semiconductor, the data stored in storage device 104 is updated to incorporate the change. Therefore, measurement of temperature T_{J} and main current I_{C} of semiconductor device 1 can be continued without any error caused by peeling or breakage of the bonding wires.

It should be understood that the embodiments disclosed herein are illustrative and non-restrictive in every respect. The scope of the present application is defined by the scope of the claims, rather than the description above, and is intended to include any modifications within the meaning and scope equivalent to the scope of the claims.

### REFERENCE SIGNS LIST

1, 1A semiconductor device; 2, 2A power semiconductor element; 3, 3A parasitic resistance component; 4 collector main terminal; 4A drain main terminal; 5, 5A gate terminal; 6 emitter reference terminal; 6A source reference terminal; 7 emitter main terminal; 7A source main terminal; 8 gate driver; 101 semiconductor characteristics measuring apparatus; 102 first potential difference measuring device; 103 second potential difference measuring device; 104 storage device; 105 processing device; 106 current information; 107 temperature information; 150 power module; I_{C} collector current (main current); I_{D} drain current (main current); T_{J} temperature; V_{CE}, V_{DS} first potential difference; V_{CEX}, V_{EEX} threshold magnification rate; V_{DST} threshold value of first potential difference V_{DS}; V_{EE}, V_{SS} second potential difference.

1. A semiconductor characteristics measuring apparatus for estimating a temperature of a semiconductor device and a main current flowing through the semiconductor device,
the semiconductor device including:
a power semiconductor element having a first main electrode, a second main electrode, and a control electrode to control the main current flowing between the first main electrode and the second main electrode; and
a plurality of connection terminals, each of the plurality of connection terminals being connected to any one of the first main electrode, the second main electrode and the control electrode,
the semiconductor characteristics measuring apparatus comprising:
a first potential difference measuring device to measure a first potential difference based on a potential difference between two connection terminals connected to the first main electrode and the second main electrode, respectively, of the plurality of connection terminals;
a second potential difference measuring device to measure a second potential difference between a first connection terminal and a second connection terminal of the plurality of connection terminals, the first connection terminal being connected to a current path of the main current to or from the second main electrode, the second connection terminal being connected to the second main electrode or connected to the current path at a position closer to the second main electrode than the first connection terminal;
a storage device to store data indicating a first relationship and data indicating a second relationship, the first relationship being a relationship among the first potential difference, a temperature of the power semiconductor element and the main current, the second relationship being a relationship among the second potential difference, the temperature of the power semiconductor element and the main current; and
a processing device, wherein
the processing device
obtains a measurement value of the first potential difference from the first potential difference measuring device,
obtains a measurement value of the second potential difference from the second potential difference measuring device,
specifies, from the data indicating the first relationship, a value of the temperature of the power semiconductor element and a value of the main current corresponding to the measurement value of the first potential difference,
specifies, from the data indicating the second relationship, a value of the temperature of the power semiconductor element and a value of the main current corresponding to the measurement value of the second potential difference, and
when the value of the temperature of the power semiconductor element and the value of the main current specified based on the measurement value of the first potential difference match the value of the temperature of the power semiconductor element and the value of the main current specified based on the measurement value of the second potential difference, outputs the matching value of the temperature and the matching value of the main current as estimates at a present time point.

2. The semiconductor characteristics measuring apparatus according to claim 1, wherein
the processing device
sets a candidate value of the temperature,
specifies, from the data indicating the first relationship, a value of the main current corresponding to the measurement value of the first potential difference and the candidate value of the temperature,
specifies, from the data indicating the second relationship, a value of the main current corresponding to the measurement value of the second potential difference and the candidate value of the temperature, and
when the value of the main current specified based on the measurement value of the first potential difference and the candidate value of the temperature matches the value of the main current specified based on the measurement value of the second potential difference and the candidate value of the temperature, outputs the candidate value of the temperature and the matching value of the main current as estimates at a present time point.

3. The semiconductor characteristics measuring apparatus according to claim 2, wherein
the processing device sequentially sets candidate values of the temperature by changing the temperature by a step width from an initial value, and
the processing device
for each of the sequentially set candidate values of the temperature, calculates a difference between the value of the main current specified from the data indicating the first relationship and the value of the main current specified from the data indicating the second relationship, and
when a sign of a value of the difference calculated for a previously set candidate value of the temperature is different from a sign of a value of the difference calculated for a currently set candidate value of the temperature, outputs the currently set candidate value of the temperature and the value of the main current corresponding thereto as estimates at a present time point.

4. The semiconductor characteristics measuring apparatus according to claim 3, wherein
the processing device
calculates a residual, the residual being a difference between the value of the difference calculated for the previously set candidate value of the temperature and the value of the difference calculated for the currently set candidate value of the temperature, and
when the sign of the value of the difference calculated for the previously set candidate value of the temperature is different from a sign of the calculated residual, reverses a sign of the step width.

5. The semiconductor characteristics measuring apparatus according to claim 1, wherein
the power semiconductor element is a metal oxide semiconductor field effect transistor (MOSFET), and
the processing device
specifies, from the data indicating the first relationship, a value of the main current corresponding to a previously output estimate of the temperature of the power semiconductor element and the measurement value of the first potential difference, as a first current value, and
when the measurement value of the first potential difference is equal to or less than a threshold value, outputs the previously output estimate of the temperature of the power semiconductor element and the first current value as estimates at a present time point.

6. The semiconductor characteristics measuring apparatus according to claim 1, wherein
when the first potential difference measured currently by the first potential difference measuring device changes by a first threshold magnification rate or more with respect to the first potential difference measured previously by the first potential difference measuring device, or when the second potential difference measured currently by the second potential difference measuring device changes by a second threshold magnification rate or more with respect to the second potential difference measured previously by the second potential difference measuring device, the processing device corrects a value of the first potential difference in the data indicating the first relationship and a value of the second potential difference in the data indicating the second relationship by the observed magnification rates.

7. A semiconductor characteristics measuring method for estimating a temperature of a semiconductor device and a main current flowing through the semiconductor device,
the semiconductor device including:
a power semiconductor element having a first main electrode, a second main electrode, and a control electrode to control the main current flowing between the first main electrode and the second main electrode; and
a plurality of connection terminals, each of the plurality of connection terminals being connected to any one of the first main electrode, the second main electrode and the control electrode,
the semiconductor characteristics measuring method comprising:
obtaining, by a processing device, a measurement value of a first potential difference based on a potential difference between two connection terminals connected to the first main electrode and the second main electrode, respectively, of the plurality of connection terminals;
obtaining, by the processing device, a measurement value of a second potential difference between a first connection terminal and a second connection terminal of the plurality of connection terminals, the first connection terminal being connected to a current path of the main current to or from the second main electrode, the second connection terminal being connected to the second main electrode or connected to the current path at a position closer to the second main electrode than the first connection terminal;
specifying, by the processing device from data indicating a first relationship stored in a storage device, a value of a temperature of the power semiconductor element and a value of the main current corresponding to the measurement value of the first potential difference, the first relationship being a relationship among the first potential difference, the temperature of the power semiconductor element and the main current;
specifying, by the processing device from data indicating a second relationship stored in the storage device, a value of the temperature of the power semiconductor element and a value of the main current corresponding to the measurement value of the second potential difference, the second relationship being a relationship among the second potential difference, the temperature of the power semiconductor element and the main current; and
when the value of the temperature of the power semiconductor element and the value of the main current specified based on the measurement value of the first potential difference match the value of the temperature of the power semiconductor element and the value of the main current specified based on the measurement value of the second potential difference, outputting, by the processing device, the matching value of the temperature and the matching value of the main current as estimates at a present time point.

8. The semiconductor characteristics measuring method according to claim 7, further comprising
setting, by the processing device, a candidate value of the temperature, wherein
the specifying a value of a temperature of the power semiconductor element and a value of the main current corresponding to the measurement value of the first potential difference includes specifying, from the data indicating the first relationship, a value of the main current corresponding to the measurement value of the first potential difference and the candidate value of the temperature,
the specifying a value of the temperature of the power semiconductor element and a value of the main current corresponding to the measurement value of the second potential difference includes specifying, from the data indicating the second relationship, a value of the main current corresponding to the measurement value of the second potential difference and the candidate value of the temperature, and
the outputting the matching value of the temperature and the matching value of the main current as estimates at a present time point includes when the value of the main current specified based on the measurement value of the first potential difference and the candidate value of the temperature matches the value of the main current specified based on the measurement value of the second potential difference and the candidate value of the temperature, outputting the candidate value of the temperature and the matching value of the main current as estimates at the present time point.

9. The semiconductor characteristics measuring method according to claim 8, wherein
the setting a candidate value of the temperature includes sequentially setting candidate values of the temperature by changing the temperature by a step width from an initial value,
the semiconductor characteristics measuring method further comprising:
for each of the sequentially set candidate values of the temperature, calculating, by the processing device, a difference between the value of the main current specified based on the measurement value of the first potential difference and the candidate value of the temperature and the value of the main current specified based on the measurement value of the second potential difference and the candidate value of the temperature; and
when a sign of a value of the difference calculated for a previously set candidate value of the temperature is different from a sign of a value of the difference calculated for a currently set candidate value of the temperature, outputting, by the processing device, the currently set candidate value of the temperature and the value of the main current corresponding thereto as estimates at a present time point.

10. The semiconductor characteristics measuring method according to claim 9, further comprising:
calculating, by the processing device, a residual, the residual being a difference between the value of the difference calculated for the previously set candidate value of the temperature and the value of the difference calculated for the currently set candidate value of the temperature; and
when the sign of the value of the difference calculated for the previously set candidate value of the temperature is different from a sign of the calculated residual, reversing, by the processing device, a sign of the step width.

11. The semiconductor characteristics measuring method according to claim 7, wherein
the power semiconductor element is a metal oxide semiconductor field effect transistor (MOSFET), and
the semiconductor characteristics measuring method further comprising:
specifying, by the processing device from the data indicating the first relationship, a value of the main current corresponding to a previously output estimate of the temperature of the power semiconductor element and the measurement value of the first potential difference, as a first current value; and
when the measurement value of the first potential difference is equal to or less than a threshold value, outputting the previously output estimate of the temperature of the power semiconductor element and the first current value as estimates at a present time point.

12. The semiconductor characteristics measuring method according to claim 7, further comprising
when the first potential difference measured currently changes by a first threshold magnification rate or more with respect to the first potential difference measured previously, or when the second potential difference measured currently changes by a second threshold magnification rate or more with respect to the second potential difference measured previously, correcting, by the processing device, a value of the first potential difference in the data indicating the first relationship and a value of the second potential difference in the data indicating the second relationship by the observed magnification rates.

13. A non-transitory computer readable medium storing instructions that, when executed by a processing device for estimating a temperature of a semiconductor device and a main current flowing through the semiconductor device, cause the processing device to perform operations,
the semiconductor device including:
a power semiconductor element having a first main electrode, a second main electrode, and a control electrode to control the main current flowing between the first main electrode and the second main electrode; and
a plurality of connection terminals, each of the plurality of connection terminals being connected to any one of the first main electrode, the second main electrode and the control electrode,
the operations comprising:
obtaining a measurement value of a first potential difference based on a potential difference between two connection terminals connected to the first main electrode and the second main electrode, respectively, of the plurality of connection terminals;
obtaining a measurement value of a second potential difference between a first connection terminal and a second connection terminal of the plurality of connection terminals, the first connection terminal being connected to a current path of the main current to or from the second main electrode, the second connection terminal being connected to the second main electrode or connected to the current path at a position closer to the second main electrode than the first connection terminal;
specifying, from data indicating a first relationship stored in a storage device, a value of a temperature of the power semiconductor element and a value of the main current corresponding to the measurement value of the first potential difference, the first relationship being a relationship among the first potential difference, the temperature of the power semiconductor element and the main current;
specifying, from data indicating a second relationship stored in the storage device, a value of the temperature of the power semiconductor element and a value of the main current corresponding to the measurement value of the second potential difference, the second relationship being a relationship among the second potential difference, the temperature of the power semiconductor element and the main current; and
when the value of the temperature of the power semiconductor element and the value of the main current specified based on the measurement value of the first potential difference match the value of the temperature of the power semiconductor element and the value of the main current specified based on the measurement value of the second potential difference, outputting the matching value of the temperature and the matching value of the main current as estimates at a present time point.
